(19) United States
(12) Patent Application Publication
(10) Pub. No.: US 2023/0283107 A1
(43) Pub. Date: Sep. 7, 2023

(54) CHARGING DEVICE AND ELECTRONIC DEVICE ASSEMBLY

(71) Applicant: GUANGDONG OPPO MOBILE TELECOMMUNICATIONS CORP., LTD., Dongguan (CN)

(72) Inventor: Zhongyu AN, Dongguan (CN)

(21) Appl. No.: 18/317,446

(22) Filed: May 15, 2023

Related U.S. Application Data
(63) Continuation of application No. PCT/CN2021/115826, filed on Aug. 31, 2021.

(30) Foreign Application Priority Data
Nov. 16, 2020 (CN) 202011283946.5

(51) Int. Cl. H02J 50/00; H02J 50/10; H02J 7/00; H05K 5/02

(52) U.S. Cl. CPC H02J 50/005; H02J 7/0044; H02J 50/10; H05K 5/0217; H05K 5/0247

(57) ABSTRACT

A charging device can include a first housing, a second housing, a charging assembly, and a holder. The second housing can be rotatably connected to the first housing and moveable relative to the first housing. The second housing can be configured to hold an electronic device. The charging assembly can be received in the second housing and configured to charge the electronic device. The holder can be connected to the first housing, and the holder can be moveable along with a movement of the second housing, enabling at least a portion of the holder to be switched between a protruding state, in which the portion of the holder extends out of the first housing, and a receiving state, in which the portion of the holder is received in the first housing. An electronic device assembly including the charging device is also provided.

### CROSS REFERENCE

This application is a continuation of International Application No. PCT/CN2021/115826, filed Aug. 31, 2021, which claims priority to Chinese Application No. 202011283946.5, filed Nov. 16, 2020, the entire disclosures of which are incorporated herein by reference.

### TECHNICAL FIELD

This disclosure relates to the field of electronic products, and in particular, to a charging device and an electronic device assembly.

### BACKGROUND

As electronic devices continue to develop and become more popular, their numbers are constantly increasing. As a result, charging devices, which are peripheral products of electronic devices, are attracting more and more attention.

### SUMMARY

In view of above, a charging device is provided in a first aspect of the disclosure. The charging device includes a first housing, a second housing, a charging assembly and a holder. The second housing is connected to the first housing and rotatable relative to the first housing. The second housing is configured to hold an electronic device. The charging assembly is received in the second housing. The charging assembly is configured to charge the electronic device. The holder is connected to the first housing. The holder is rotatable along with a rotation of the second housing. The holder is configured to be switchable between a protruding state and a receiving state. The protruding state is in which the holder extends out of the first housing, and the receiving state is in which the holder is received in the first housing.

A charging device is provided in a second aspect of the disclosure. The charging device comprises a first housing, a second housing, a charging assembly and a motor assembly. The second housing is connected to the first housing and the second housing is rotatable relative to the first housing. The second housing is configured to hold an electronic device. The charging assembly is received in the second housing. And the charging assembly is configured to charge the electronic device. The motor assembly is configured to receive a first control signal and a second control signal. The motor assembly is configured to start working under the control of the first control signal to drive the second housing to rotate relative to the first housing. The motor assembly is configured to stop working under the control of the second control signal.

### BRIEF DESCRIPTION OF THE DRAWINGS

To describe technical solutions in embodiments of the disclosure more clearly, the following will give an illustration to accompanying drawings required for describing embodiments of the disclosure.

FIG. 1 is a schematic perspective structural view of a charging device in a horizontal state in an embodiment of the disclosure.

FIG. 2 is a schematic cross-sectional view of the charging device in FIG. 1, taken along line A-A.

FIG. 3 is a schematic perspective structural view of a charging device in a vertical state in an embodiment of the disclosure.

FIG. 4 is a schematic cross-sectional view of the charging device in FIG. 3, taken along line B-B.

FIG. 5 is an exploded view of a charging device in an embodiment of the disclosure.

FIG. 6 is a schematic perspective structural view of the first housing in an embodiment of the disclosure.

FIG. 7 is an exploded view of a portion of a charging device in an embodiment of the disclosure.

FIG. 8 is a schematic cross-sectional view of the charging device in FIG. 1 in an embodiment of the disclosure, taken along line C-C.

FIG. 9 is an exploded view of a portion of a charging device in another embodiment of the disclosure.

FIG. 10 is a schematic cross-sectional view of the charging device in FIG. 1 in another embodiment of the disclosure, taken along line C-C.

FIG. 11 is a schematic cross-sectional view of the charging device in FIG. 1 in another embodiment of the disclosure, taken along line A-A.

FIG. 12 is a schematic cross-sectional view of the charging device in FIG. 1 when the charging device is in a rearward state in an embodiment of the disclosure, taken along line A-A.

FIG. 13 is a schematic partial view of FIG. 12.

FIG. 14 is an exploded view of a portion of a charging device in another embodiment of the disclosure.

FIG. 15 is an exploded view of a portion of a charging device in another embodiment of the disclosure.

FIG. 16 is a schematic structural view of a motor assembly in an embodiment of the disclosure.

FIG. 17 is a schematic structural view of a motor assembly in another embodiment of the disclosure.

FIG. 18 is an exploded view of a portion of a charging device in another embodiment of the disclosure.

FIG. 19 is an exploded view of a portion of a charging device in another embodiment of the disclosure.

FIG. 20 is a schematic structural view of a connection member and a third rotation shaft in an embodiment of the disclosure.

FIG. 21 is a schematic structural view of the cooperation structure of the connection member, the third rotation shaft, and the motor assembly in an embodiment of the disclosure.

FIG. 22 is a schematic cross-sectional view of the charging device in FIG. 1 in another embodiment of the disclosure, taken along line A-A.

FIG. 23 is an exploded view of a charging assembly in an embodiment of the disclosure.

FIG. 24 is an exploded view of a portion of a charging device in another embodiment of the disclosure.

FIG. 25 is a schematic cross-sectional view of the charging device in FIG. 1 in another embodiment of the disclosure, taken along line D-D.

FIG. 26 is an exploded view of a third sub-housing, a transmission member, and a holder in an embodiment of the disclosure.

FIG. 27 is a schematic partial cross-sectional view of a charging device in an embodiment of the disclosure.

FIG. 28 is a schematic perspective view of a transmission member in an embodiment of the disclosure.

FIG. 29 is a schematic perspective structural view of a transmission member and a holder in an embodiment of the disclosure.

FIG. 30 is a schematic view of the electronic structure of a charging device in an embodiment of the disclosure.

FIG. 31 is a schematic view of the electronic structure of the charging device in another embodiment of the disclosure.

FIG. 32 is a schematic view of the electronic structure of the charging device in another embodiment of the disclosure.

FIG. 33 is a schematic view of the electronic structure of the charging device in another embodiment of the disclosure.

FIG. 34 is a schematic view of the electronic structure of the charging device in another embodiment of the disclosure.

FIG. 35 is a schematic view of the electronic structure of the charging device in another embodiment of the disclosure.

FIG. 36 is a schematic structural view of an electronic device assembly in an embodiment of the disclosure.

FIG. 37 is a schematic cross-sectional view of FIG. 36, taken along line E-E.

### DETAILED DESCRIPTION

The following are embodiments of the disclosure, and various modifications can be made by those skilled in the art without departing from the principles of the disclosure. These modifications are also considered to fall within the scope of the disclosure.

A charging device according to the present disclosure can include a first housing, a second housing, a charging assembly, and a holder. The second housing can be rotatably connected to the first housing and be moveable relative to the first housing. The second housing can be configured to hold an electronic device. The charging assembly can be received in the second housing and can be configured to charge the electronic device. The holder can be connected to the first housing. The holder can be moveable along with a movement of the second housing to enable at least a portion of the holder to be switched between a protruding state and a receiving state. The protruding state can be a state in which the portion of the holder extends out of the first housing, and the receiving state can be a state in which the portion of the holder is received in the first housing.

The second housing can be configured to be rotatable relative to the first housing. Alternatively, the second housing can be configured to be translational and rotatable relative to the first housing.

When the angle between the second housing and the first housing is a preset angle, the second housing can be configured to abut against the holder. When the angle between the second housing and the first housing is larger than the preset angle, the second housing can be configured to drive the holder to rotate.

The first housing can include a connected first sub-housing and a second sub-housing. The first sub-housing and the second sub-housing can be configured to define a first receiving space. The first housing can further include a protruding portion arranged on the side of the second sub-housing distal from the first sub-housing. The protruding portion can include two opposing first side walls and a second side wall connecting between the two first side walls. The first side wall and the second side wall can define a second receiving space. The second receiving space is connected to with the first receiving space. The second housing can be rotatably connected to the first side wall.

A first rotation groove can be provided on the side of the first side wall proximal to the second receiving space. The second housing includes a third sub-housing and a fourth sub-housing, and the third sub-housing and the fourth sub-housing is connected to each other. The third sub-housing is closer to the first sub-housing than the fourth sub-housing, the third sub-housing and the fourth sub-housing are surround to define a third receiving space. The third sub-housing includes a bottom wall and a side wall bent and connected to at least part of the periphery of the bottom wall. A first through hole is opened on the side wall. The charging device further includes a first rotating shaft. One end of the first rotating shaft is arranged in the third receiving space, and the end of the first rotating shaft is connected to the third sub-housing. The other end of the first rotating shaft passes through the first through hole is arranged outside the third receiving space, and the other end of the first rotating shaft is arranged in the first rotation groove.

A second rotation groove can be provided on a side of the first side wall, proximal to the second receiving space. The charging device further includes a second rotating shaft. One end of the second rotating shaft is connected to the holder, and another end of the second rotating shaft is arranged in the second rotation groove.

A slot can be provided on a side of the holder proximal to the first sub-housing. One end of the second rotating shaft can be disposed in the slot.

When the holder is in the receiving state, the surface of the holder facing away from the first sub-housing can be flush with the surface of the protruding portion facing away from the first sub-housing.

The first housing has a first surface and a second surface opposite to each other, and a third surface connecting the first surface and the second surface. At least part of the second surface abuts the second housing. When the holder is in the protruding state, the holder protrudes from the second surface beyond the first housing.

A clearance space is defined between the holder and the second housing. The clearance space can allow the second housing to rotate relative to the first housing.

A first rotation portion is provided on at least part of the surface of the holder near the fourth sub-housing. A second rotation portion is provided on the surface of the fourth sub-housing near the holder. The second rotation portion is further from the first sub-housing than the first rotation portion, and the second rotation portion is separated from the surface of the holder closing the first sub-housing by a distance. The holder, the first rotation portion, the fourth sub-housing, and the second rotation portion can collectively surround an area to define the clearance space.

A part of the surface of the fourth sub-housing near the side of the holder is provided with a third rotation portion. The third rotation portion can be closer to the first sub-housing as compared to the first rotation portion. When the charging device is in the initial state, the third rotation portion abuts the first rotation portion. When the electronic device moves from a rearward state to a vertical state, the third rotation portion can be separated from the first rotation portion. When the electronic device moves from the vertical state to the rearward state, the third rotation portion can abut against the first rotation portion again and drive the first rotation portion to rotate.

A side surface of the holder distal from the first sub-housing, a side surface of the second rotation portion distal from the first sub-housing, and a side surface of the fourth sub-housing facing away from the first sub-housing be can flush with each other.

The first housing can include a connected first sub-housing and a second sub-housing. The first sub-housing and the second sub-housing can surround an area to define a first receiving space. The second housing can include a connected third sub-housing and a fourth sub-housing. The third sub-housing can be closer to the first sub-housing than the fourth sub-housing. The third sub-housing and the fourth sub-housing can surround an area to define a third receiving space. The charging device can further include a motor assembly that is arranged in the first receiving space. The motor assembly can be rotatably connected to the second housing, and the motor assembly can drive the second housing to rotate relative to the first housing.

The motor assembly can include a motor, a screw rod, and a slider. The screw rod can be connected to the motor. The slider can be sheathed on the screw rod, and the slider can be screwed to the screw rod. The slider may be provided with a first sliding portion. The motor assembly can also include a second sliding portion. The first sliding portion can cooperate with the second sliding portion to slide the slider on the screw rod when the motor operates. A third rotation groove can open on a side of the slider proximal to the second sub-housing. The charging device may further include a third rotation shaft. One end of the third rotation shaft can be connected to the second housing, and the other end of the third rotation shaft can be arranged in the third rotation groove.

The third rotation groove can extend toward the direction of the first sub-housing.

The motor assembly may further include a support member that is connected to the first sub-housing. A side of the support member, which is distal from the first sub-housing, can be provided with a sliding groove. A side of the slider proximal to the support member can be provided with a sliding block. The sliding block can slide in the sliding groove.

The motor assembly may further include a support member and a guide rod. The support member can include a bottom plate, and side plates bent and connected to opposite ends of the bottom plate. The bottom plate and the side plate can surround an area to define a sliding space. The slider can be arranged in the sliding space. A second through hole can be opened on the side plate. The screw rod can pass through the second through hole and the slider. The side plate can also be provided with a third through hole. The slider can be provided with a fourth through hole. The guide rod can be connected to the side plate, and the guide rod may pass through the third through hole and the fourth through hole. The slider can slide along the guide rod through the fourth through hole.

The motor assembly can further include an elastic member arranged in the sliding space. The elastic member may be sleeved on the guide rod, and the elastic member can be arranged between the side plate and the slider. When the charging device is in an initial state, the elastic member can abut the side plate and the slider, and the elastic member can be in a compressed state.

The charging device can further include a distance sensor. The distance sensor can include a Hall magnet and a Hall support member. The Hall magnet may be installed on the Hall support member, and the Hall support member can be sleeved on an end of the screw rod, distal from the motor.

The first housing can further include a protruding portion provided on a side of the second sub-housing distal from the first sub-housing. The protruding portion can include two opposite first side walls, and a second side wall connecting the two first side walls. The first side wall and the second side wall can surround and area to define a second receiving space. The second receiving space is connected to the first receiving space. The second housing can further include a connection member having a first connection portion, a second connection portion, and a third connection portion. Part of the first connection portion can be arranged in the third receiving space. The first connection portion can be connected to the third sub-housing. The second connection portion may be bent and connected to the first connection portion, and the second connection portion can pass through the second receiving space and be arranged in the first receiving space. The third connection portion can be bent and connected to the second connection portion. The third connection portion can be arranged in the first receiving space, and one end of the third rotation shaft can be connected to the third connection portion.

Prior to the motor assembly driving the second housing to rotate relative to the first housing, the motor assembly can drive the second housing to move relative to the first housing to define the aforementioned clearance space.

The first rotation groove can extend toward a direction of movement of the first housing.

The charging device can have a horizontal state and a vertical state. In the horizontal state, the second housing can be parallel to the first housing state, and in the vertical state, an angle can be formed between the second housing and the first housing. The horizontal state can include an initial state and a rearward state. In the initial state, the second rotation portion can abut the side surface of the holder proximal to the fourth sub-housing. In the rearward state, the second housing moves relative to the first housing such that the second rotation portion is spaced apart from the side surface of the holder proximal to the fourth sub-housing by a distance. When the charging device moves from the initial state to the rearward state, the motor begins to operate, driving the slider to slide through the screw rod, and driving the second housing to move relative to the first housing. When the charging device is in the rearward state, the first rotating shaft abuts the first side wall to define the groove wall of the first rotation groove. When the charging device moves from the rearward state to the vertical state, the slider continues to slide, driving the other end of the third rotation shaft to slide in the direction of the first sub-housing in the third rotation groove, and driving the second housing to rotate relative to the first housing.

The second housing can include a first end and a second end that are disposed opposite one another. The first end can be closer to the holder than the second end. The motor assembly can be rotatably connected to the first end.

The charging assembly can be arranged in the third receiving space, where the charging assembly includes a charging coil and a heat dissipation bracket. The charging coil can be arranged on the heat dissipation bracket.

The charging device can further include a transmission member. When the second housing rotates relative to the first housing, the second housing can drive the transmission member to rotationally drive the holder to rotate.

The charging device can further include a transmission member. The transmission member can detachably connect the second housing to the holder. When the second housing has moved away from the first housing by a distance that is less than a preset value, there is a gap between the transmission member and the holder. When the second housing has moved away from the first housing by a distance equal to the preset value, the second housing can drive the transmission member to connect to the holder. When the second housing has moved away from the first housing by a distance that is greater than the preset value, the second housing can drive the transmission member, causing the holder to move.

When the second housing rotates relative to the first housing, the second housing is separated from the transmission member.

In at least one alternative embodiment, the charging device can include a first housing and a second housing. The second housing can be connected to the first housing, and the second housing can translate and rotate relative to the first housing. The second housing can receive an electronic device. The charging device can also include a charging assembly arranged in the second housing, which can charge the electronic device. The charging device can also include a motor assembly that receives a first control signal. The first control signal can cause the motor assembly to drive the second housing to translate and rotate relative to the first housing. The motor assembly may also receive a second control signal that causes the motor assembly to stop.

The charging device can further include a processor. The processor may be electrically connected to the motor assembly. The processor can be used to send the first control signal and the second control signal.

The motor assembly can include a motor and a slider. The motor may be configured to drive the slider to slide, which can drive the second housing to translate and rotate relative to the first housing. The charging device can also include a distance sensor. The distance sensor may be electrically connected to the processor, and the distance sensor may be configured to detect the sliding distance of the slider. When the sliding distance of the slider is greater than or equal to a preset distance, the processor may be configured to send the second control signal.

The charging device can further include a main board and a secondary board. The secondary board may be electrically connected to the main board, and the processor may be arranged on the main board. When the motor assembly begins to operate, the distance sensor can send a distance signal to the processor on the main board via the secondary board, and the processor may be further configured to obtain the sliding distance of the slider according to the distance signal.

The charging device can further include a speaker. The speaker may be electrically connected to the processor. When the processor sends the first control signal, the processor may be further configured to send an audio signal to the speaker, which may cause the speaker to output a sound. When the processor sends the second control signal to the motor assembly, the processor may be further configured to stop sending the audio signal to the speaker, which may cause the speaker to stop outputting the sound.

The charging device can further include a first switch and a second switch. Both of the first switch and the second switch may be electrically connected to the processor. When the first switch is pressed, the first switch may be configured to send a vertical signal to the processor, and the processor may be further configured to send the first control signal to the motor assembly according to the vertical signal, which may cause the output shaft of the motor assembly to rotate in the first direction. When the second switch is pressed, the second switch may be configured to send a horizontal signal to the processor, and the processor may be configured to send a third control signal to the motor assembly according to the horizontal signal, which may cause the output shaft of the motor assembly to rotate in a second direction. The first direction may be opposite to the second direction.

The processor may be further configured to obtain the pressing time of the first switch according to the vertical signal. The processor may be further configured to judge whether the pressing time is less than a preset time. When the pressing time is less than the preset time, and when the sliding distance of the slider is equal to the preset distance, the processor may send the second control signal to the motor assembly. When the pressing time is greater than or equal to the preset time, and when the touch force on the first switch is removed, the processor may send the second control signal to the motor assembly.

The charging device can further include a transceiver. The transceiver may be electrically connected to the motor assembly, and the transceiver may be configured to receive the first control signal and the second control signal sent from the terminal.

The charging device can further include a processor. The processor may be electrically connected to the transceiver and the motor assembly. The transceiver may be further configured to receive the fourth control signal from the terminal, and the transceiver may be further configured to send the fourth control signal to the processor. The processor may be further configured to control the motor assembly according to the fourth control signal, which can cause the motor assembly to start operating or stop operating.

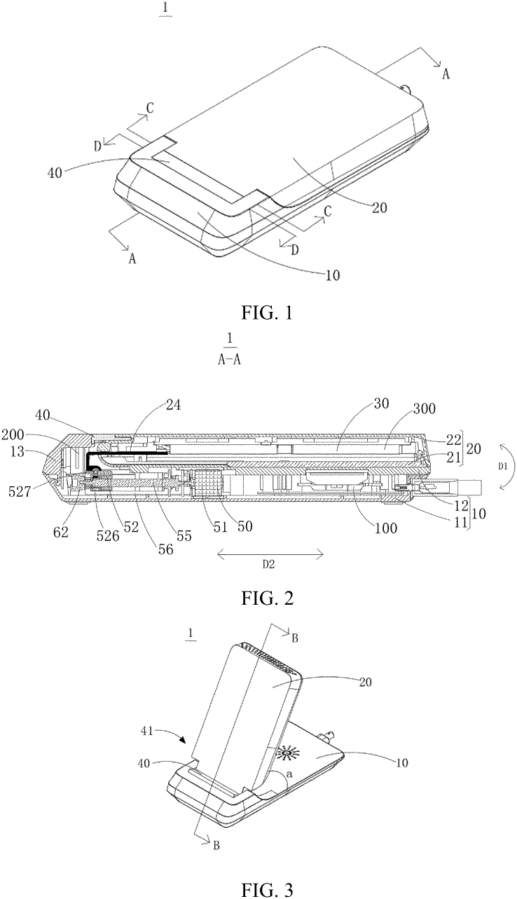

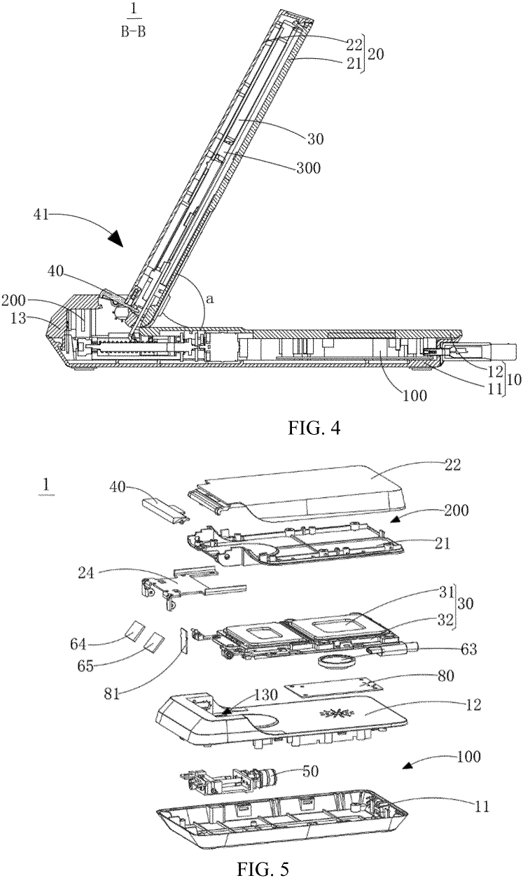

The electronic device assembly can include an electronic device and a charging device. The electronic device can include an induction coil and a battery. The charging coil and the induction coil can cooperate to charge the battery. Specific reference is made to FIGS. 1 to 4. FIG. 1 is a schematic perspective structural view of a charging device in a horizontal state in an embodiment of the disclosure. FIG. 2 is a schematic cross-sectional view of the charging device in FIG. 1, taken along line A-A. FIG. 3 is a schematic perspective structural view of a charging device in a vertical state in an embodiment of the disclosure. FIG. 4 is a schematic cross-sectional view of the charging device in FIG. 3, taken along line B-B. The embodiment shown in FIGS. 1 to 4 provides a charging device 1. The charging device 1 includes a first housing; a second housing, rotatably connected to the first housing and moveable relative to the first housing; the second housing configured to hold an electronic device; a charging assembly, received in the second housing and configured to charge the electronic device; and a holder connected to the first housing, and the holder is moveable along with a movement of the second housing, enabling at least a portion of the holder to be switched between a protruding state, in which the portion of the holder extends out of the first housing, and a receiving state, in which the portion of the holder is received in the first housing.

The charging device 1 provided in this embodiment is configured for charging an electronic device 2. The charging device 1 can be connected to an external power source, and the electronic device 2 can be charged by using the external electric energy through the charging device 1 as an intermediary. In at least one alternative embodiment, the charging device 1 itself has a battery 5 inside, and the charging device 1 can transmit the electric energy of its own battery 5 to the electronic device 2 for charging. In addition, the electronic device 2 can be, but is not limited to, a mobile phone, a tablet computer, a notebook computer, a palmtop computer, a personal computer (Personal Computer, PC), a personal digital assistant (Personal Digital Assistant, PDA), a portable media player (Portable Media Player, PMP), navigation devices, wearable devices, smart bracelets, pedometers or other mobile terminal, as well as a fixed terminal such as digital TV or desktop computer. In this application, the electronic device 2 is shown as a mobile phone for schematic illustration.

The charging device 1 provided in this embodiment includes a first housing 10 and a second housing 20, and the second housing 20 is configured to hold the electronic device 2. The first housing 10 can be understood as a lower shell, and the second shell 20 can be understood as an upper shell. The first housing 10 is connected to the second housing 20 so that the second housing 20 can move relative to the first housing 10. In other words, the first housing 10 may be stationary, while the second housing 20 moves relative to the first housing 10. In at least one alternative embodiment, the first housing 10 is rotatably connected to the second housing 20; or, the first housing 10 is translationally and rotatably connected to the second housing 20. It can also be understood the second housing 20 can move relative to the first housing 10, or the second housing 20 can translate and rotate relative to the first housing 10. In FIG. 2, direction D1 indicates the rotation direction of the second housing 20 relative to the first housing 10, and direction D2 indicates the translation direction of the second housing 20 relative to the first housing 10. Since the electronic device 2 is placed on the second housing 20, when the second housing 20 translates and rotates relative to the first housing 10, the electronic device 2 will also move together with the second housing 20.

This embodiment provides a charging device 1 of a vertical-horizontal conversion type. In other words, the charging device 1 can be converted between two states: a horizontal state (as shown in FIG. 1) and a vertical state (as shown in FIG. 3). The horizontal state refers to a state in which the second housing 20 is parallel to the first housing 10, and the second housing 20 may abut against the surface of the first housing 10. The vertical state is a state where an angle is formed between the second housing 20 and the first housing 10, caused by the second housing 20 being rotated relative to the first housing 10. One end of the second housing 20 is turned away from the first housing 10, which makes the second housing 20 no longer parallel to the first housing 10, but forms a certain angle. In at least one alternative embodiment, in the vertical state, the angle between the second housing 20 and the first housing 10 may be greater than 0° and less than 90°. When the charging device 1 is in the vertical state, the electronic device 2 will also rotate together with the second housing 20 on the second housing 20 so that the electronic device 2 “stands up”, which allows the user to view the electronic device at different angles.

The charging device 1 provided in this embodiment further includes a charging assembly 30, and the charging assembly 30 is arranged in the second housing 20. In this embodiment, the charging assembly 30 is configured to charge the electronic device 2. In at least one alternative embodiment, the charging device 1 can transmit electric energy through wires, or the charging device 1 can transmit electric energy wirelessly (i.e., the charging device 1 is a wireless charging device). Therefore, the charging device 1 provided in the disclosure mainly has two functions: the function of converting between vertical and horizontal states and the function of charging. In at least one alternative embodiment, the charging assembly 30 includes a charging coil 31, and the charging coil 31 is one of the main components for charging the electronic device 2. The charging coil 31 may be a wired charging coil 31 or a wireless charging coil 31. In this embodiment, the charging coil 31 is used as the wireless charging coil 31 for illustration. At this time, the charging device 1 is the wireless charging device 1, which can further improve the convenience of using the charging device 1.

The charging device 1 provided in this embodiment also includes a holder 40. Since the disclosure provides a charging device 1 of a vertical-horizontal conversion type, and when the charging device 1 is in a vertical state, the electronic device 2 will also stand up. However, the electronic device 2 will be affected by its own gravity so that the electronic device 2 has a tendency to slide down from the second housing 20 when the charging device 1 is in the vertical state. Therefore, this embodiment provides a holder 40, which may be configured to abut against one end of the electronic device 2, thereby preventing the electronic device 2 from slipping. In at least one alternative embodiment, it can also be understood that when the charging device 1 is in a vertical state, the holder 40 and the second housing 20 can surround and form a positioning groove 41 to position the electronic device 2. Moreover, since the position of the electronic device 2 relative to the second housing 20 is limited by the holder 40, the positions of the electronic device 2 and the charging assembly 30 can be further limited, thereby improving the charging efficiency and charging stability of the charging device 1.

However, in the related art, the holder protrudes from the second housing, and the holder is fixedly connected to the second housing. In this way, the effects described above can be achieved when the charging device is in a vertical state. However, when the charging device is in a horizontal state, the holder will still protrude from the second housing, thereby affecting the flatness of the surface of the charging device. Furthermore, when the charging device is in a horizontal state, the holder limits the position of the electronic device, and electronic device cannot be arbitrarily placed on the second housing.

In order to solve the above problems, the disclosure provides the holder 40 that is movable. The holder 40 can follow the movement of the second housing 20, so that the holder 40 is switched between a protruding state, in which the portion of the holder extends out of the first housing, and a receiving state, in which the portion of the holder is received in the first housing. As described, “follow the movement” can be understood as moving along with the literal meaning. In other words, when the second housing 20 moves relative to the first housing 10, the holder 40 can move together with the second housing 20, or the second housing 20 and the holder 40 can move together. In at least one alternative embodiment, as long as the second housing 20 moves, the holder 40 moves accordingly. Alternatively, when the second housing 20 moves to a certain distance, the holder 40 starts to follow.

Moreover, in this embodiment, the holder 40 can be connected to the first housing 10. In at least one alternative embodiment, the holder 40 can be rotatably connected to the first housing 10. Alternatively, the holder 40 can be movably connected to the first housing 10. It can also be understood that the holder 40 can rotate or move relative to the first housing 10. In this embodiment, the holder 40 is connected to the first housing 10. First, a certain angle is formed between the holder 40 and the second housing 20. When the second housing 20 rotates relative to the first housing 10, various angles can be formed. Compared with the fixed angle between the holder 40 and the second housing 20 in the related art, this embodiment can meet different needs. Secondly, the holder 40 is connected to the first housing 10, and compared with the related art, the distance between the holder 40 and the end of the second housing 20 can be increased. When the electronic device 2 of the same size is limited, the size of the second housing 20 can be reduced, thereby reducing the size of the charging device 1 as a whole.

In addition, as a result of the movement of the holder 40, at least part of the holder 40 can be switched between the protruding state protruding from the first housing 10 and the receiving state being received in the first housing 10. The receiving state can be understood as when the charging device 1 is in the initial state or a state in which the holder 40 is received in the first housing 10 when the second housing 20 moves to a certain position relative to the first housing 1. In other words, the holder 40 does not extend out of the first housing 10 in the receiving state. The protruding state can be understood as when the second housing 20 moves to a certain position relative to the first housing 10, the holder 40 follows to make the holder 40 protrude from the first housing 10. In this case, the holder 40 has two functions. For example, when the charging device 1 is in a vertical state, the holder 40 can protrude from the first housing 10 so as to abut against the electronic device 2. When the charging device 1 is in a horizontal state, the holder 40 can be received in the first housing 10, so that the holder 40 will not protrude from the surface of the charging device 1, thereby improving the flatness of the surface of the charging device 1. Moreover, the electronic device 2 can also be placed anywhere on the surface of the second housing 20, not limited by the holder 40, which improves the convenience of the user.

This embodiment allows the holder 40 to switch between a protruding state and a receiving state by following the movement of the second housing 20. This limits the position of the electronic device 2 when the charging device 1 is in a vertical state and improves the surface flatness when the charging device 1 is in a horizontal state. This enhances the versatility and convenience of the charging device 1. The specific structure of the charging device 1 and how the holder 40 moves with the second housing 20 will be introduced in detail below.

As mentioned above, the second housing 20 can move relative to the first housing 10 and the holder 40 can follow the movement of the second housing 20. Several exemplary methods for how the second housing 20 can move relative to the first housing 10 and how the holder 40 can follow the movement of the second housing 20 are introduced below in this application.

In at least one alternative embodiment, for the first housing 10 and the second housing 20, the second housing 20 can rotate relative to the first housing 10, or the second housing 20 can translate and rotate relative to the first housing 10. It can also be understood that the second housing 20 can only rotate relative to the first housing 10, and the holder 40 performs a follow-up movement during the rotation of the second housing 20. In at least one alternative embodiment, the second housing 20 can translate and rotate relative to the first housing 10. In other words, the second housing 20 can translate relative to the first housing 10, and the second housing 20 can also rotate relative to the first housing 10. The holder 40 can carry out a follow-up movement during a certain period of translation and rotation of the second housing 20. For example, the holder 40 can perform a follow-up movement during the translation of the second housing 20, or the holder 40 can perform a follow-up movement during the rotation of the second housing 20. In at least one alternative embodiment, the second housing 20 can first move relative to the first housing 10, and after moving to a certain distance, the second housing 20 can then rotate relative to the first housing 10.

Additionally, when the second housing 20 is movable relative to the first housing 10, the horizontal state of the charging device 1 includes two states: an initial state and a rearward state. The initial state can be understood as the initial state when the second housing 20 neither rotates nor moves relative to the first housing 10. The rearward state is a state in which the second housing 20 has moved relative to the first housing 10 but has not yet rotated. Therefore, in the process of lifting the second housing 20 the charging device 1 first goes from the initial state to the rearward state, and then from the rearward state to the vertical state. Similarly, in the process of lowering the second housing 20, the charging device 1 first goes from the vertical state to the rearward state, and then from the rearward state to the initial state.

In at least one alternative embodiment, for the holder 40 and the second housing 20, when the second housing 20 moves relative to the first housing 10, the second housing 20 directly cooperates with the holder 40. Thus, the holder 40 is driven to move. This solution can also be understood as, when the second housing 20 moves, the second housing 20 will be connected or abutted against the holder 40 when it moves to a certain position, and when the second housing 20 continues to move, the second housing 20 will drive the holder 40 to perform a follow-up motion.

In at least one alternative embodiment, the charging device 1 further includes a transmission member 70. When the second housing 20 moves relative to the first housing 10, the second housing 20 drives the holder 40 to move through the and the indirect cooperation between the holder 40 and the transmission member 70. This solution can also be understood as, when the second housing 20 moves, the second housing 20 is not directly connected or abutted against the holder 40, but through the transmission member 70. The second housing 20 is connected to the transmission member 70, and the transmission member 70 is connected to the holder 40, so that when the second housing 20 moves, the transmission member 70 can be driven to move. When the transmission member 70 moves, it can drive the holder 40 to move, so that the movement of the second housing 20 can bring the movable holder 40 to move.

In at least one alternative embodiment, for the holder 40 and the first housing 10, the holder 40 is rotatably connected to the first housing 1, or the holder 40 is movably connected to the first housing 10. When the second housing 20 moves and drives the holder 40 to move along with it, the holder 40 also moves in various forms. For example, the holder 40 can be movably connected to the first housing 10, that is, the holder 40 can switch between the protruding state and the receiving state by moving. In at least one alternative embodiment, the holder 40 can be rotatably connected to the first housing 10. In other words, the holder 40 can switch between the protruding state and the receiving state through rotation.

Several feasible technical solutions of this application have been introduced above from different angles, and new technical solutions after permutation and combination of the above technical solutions should also belong to the scope of this application, and this application will not give examples one by one here.

This application provides certain examples, but is not limited to the examples described herein.

For example, when the second housing 20 rotates and moves relative to the first housing 10, the second housing 20 is directly matched with the holder 40. When the holder 40 is rotationally connected to the first housing 10, the second housing 20 rotates relative to the first housing 10, and when the angle between the second housing 20 and the first housing 10 is a preset angle, the second housing 20 abuts the holder 40, such that the second housing 20 is directly matched with the holder 40. When the angle between the second housing 20 and the first housing 10 is greater than the preset angle, the second housing 20 drives the holder 40 to rotate, as the holder 40 and the first housing 10 are rotationally connected to finally realize the purpose that the holder 40 rotates with the rotation of the second housing 20. Next, this application will introduce in detail the specific structure of the charging device 1 that can achieve the above purpose.

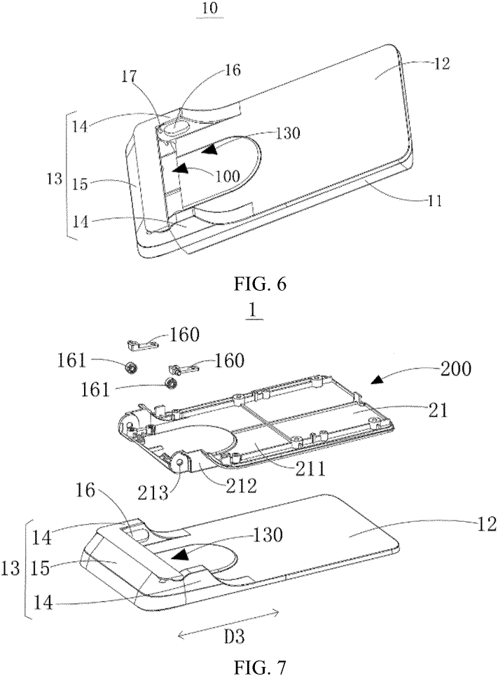

Next, this application will introduce in detail the structure of each component and the cooperative relationship between multiple components, so as to solve the above technical problems and achieve the above technical effects. First, the disclosure firstly introduces the structure of the first housing 10. Specific reference is made to FIGS. 5 and 6. FIG. 5 is an exploded view of a charging device in an embodiment of the disclosure. FIG. 6 is a schematic perspective structural view of the first housing in an embodiment of the disclosure. In this embodiment, the first housing 10 includes a connected first sub-housing 11 and a second sub-housing 12. The first sub-housing 11 and the second sub-housing 12 form a first receiving space 100. The first housing 10 further includes a protruding portion 13 located on the side of the second sub-housing 12 distal from the first sub-housing 11. The protruding portion 13 includes two first side wall 14 opposite to each other, and a second side wall 15 connecting the two first side walls 14. The first side wall 14 and the second side wall 15 surround to form a second receiving space 130 connected to the first receiving space 100. The second housing 20 may be rotatably connected to the first side wall 14.

In this embodiment, the first housing 10 is not a conventional housing structure, but is composed of a first sub-housing 11, a second sub-housing 12, and a protruding portion 13. The second sub-housing 12 and the protruding portion 13 may be of an integrated structure or separate structures. When the second sub-housing 12 and the protruding part 13 are integrally structured, it can be understood that the first housing 10 can be artificially divided into the second sub-casing 12 and the protruding part 13 in order to facilitate a clear understanding of its structural features.

In this embodiment, the first housing 10 has a certain protruding structure due to the presence of the protruding portion 13, which facilitates the translation and rotation connection between the second housing 20 and the first housing 10, and first side wall 14 and two second side walls 15 surrounded and form the second receiving space 130. The second receiving space 130 may be configured to accommodate structural parts such as the transmission member 70 and holder 40, provide installation space for these parts, and improve the appearance and performance of the charging device 1. Moreover, the second housing 20 is rotatably connected to the first side walls 14. In at least one alternative embodiment, the second housing 20 is rotatably connected to the two first side walls 14, so as to improve the rotatability of the second housing 20.

In addition, the second receiving space 130 is connected to the first receiving space 100, and a motor assembly 50 will be added in the first receiving space 100 later, and the motor assembly 50 may be configured to drive the second housing 20 to rotate, so a connection space is reserved for the second housing 20 to connect to the motor assembly 50.

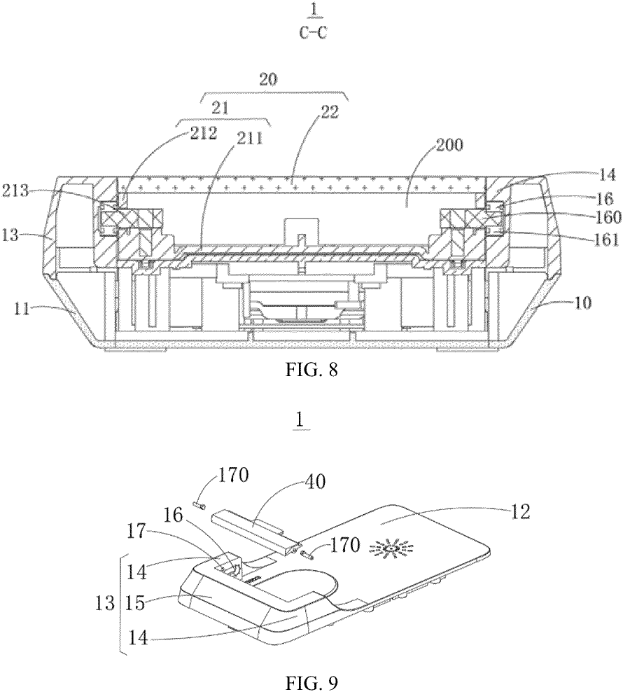

Next, the disclosure will describe in detail how the second housing 20 rotates and moves to connect with the first side wall 14. Specific reference is made to FIGS. 7 and 8. FIG. 7 is an exploded view of a portion of a charging device in an embodiment of the disclosure. FIG. 8 is a schematic cross-sectional view of the charging device in FIG. 1 in an embodiment of the disclosure, taken along line C-C. In this embodiment, the first side wall 14 is provided with a first rotation groove 16 on a side proximal to the second receiving space 130, and the second housing 20 includes a third sub-housing 21 and a fourth sub-housing 22, which are connected to each other. The third sub-housing 21 is closer to the first sub-housing 11 than the fourth sub-housing 22. The third sub-housing 21 and the fourth sub-housing 22 surrounds and forms the third receiving space 200. The third sub-housing 21 includes a bottom wall 211 and a side wall 212 that is bent and connected to at least part of the periphery of the bottom wall 211, and the side wall 212 is provided with a first through hole 213. The charging device 1 further includes a first rotation shaft 160. One end of the first rotation shaft 160 is set in the third receiving space 200, and one end of the first rotation shaft 160 is connected to the third sub-housings 21. The other end of the first rotation shaft 160 passes through the first through hole 213 and is arranged outside the third receiving space 200, and the other end of the first rotation shaft 160 is arranged at the first rotation groove 16.

In this embodiment, firstly, a first rotation groove 16 is defined on a side of the first side wall 14 proximal to the second receiving space 130. The second housing 20 includes a third sub-housing 21 and a fourth sub-housing 22. The third sub-housing 21 is closer to the first sub-housing 11 and the second sub-housing 12. The fourth sub-housing 22 can be used to receive and carry the electronic device 2. The third sub-housing 21 and the fourth sub-housing 22 surround and form a third receiving space 200, and the third receiving space 200 can be used to accommodate structural components such as the first rotation shaft 160 and the charging assembly 30. The third sub-housing 21 includes a bottom wall 211 and a side wall 212, and a first through hole 213 is defined on the side wall 212. Therefore, one end of the first rotation shaft 160 can be arranged in the third receiving space 200 and connected to the third sub-housing 21 by, for example, screws, and the other end of the first rotation shaft 160 can pass through the through hole of the side wall 212 and be arranged in the first rotation groove 16. In this way, the second housing 20 can be rotated relative to the first housing 10 by utilizing the cooperation between the first rotation groove 16 and the first rotation shaft 160. Specifically, when the first rotation shaft 160 rotates in the first rotation groove 16, since one end of the first rotation shaft 160 is connected to the third sub-housing 21, the third sub-housing 21 can be driven by the first rotation shaft 160 to rotate. Similarly, the fourth sub-housing 22 can also be driven by the third sub-housing 21 to rotate.

In at least one alternative embodiment, the other end of the first rotation shaft 160 is also sleeved with a first bearing 161, and the first bearing 161 is arranged in the first rotation groove 16. The cooperation between the first bearing 161 and the first rotation shaft 160 can further improve the rotation performance of the first rotation shaft 160.

In at least one alternative embodiment, there are two first rotation shafts 160 and two first bearings 161, which are oppositely disposed in the first rotation grooves 16 on the two first side walls 14, so as to further improve the rotation performance of the second housing 20.

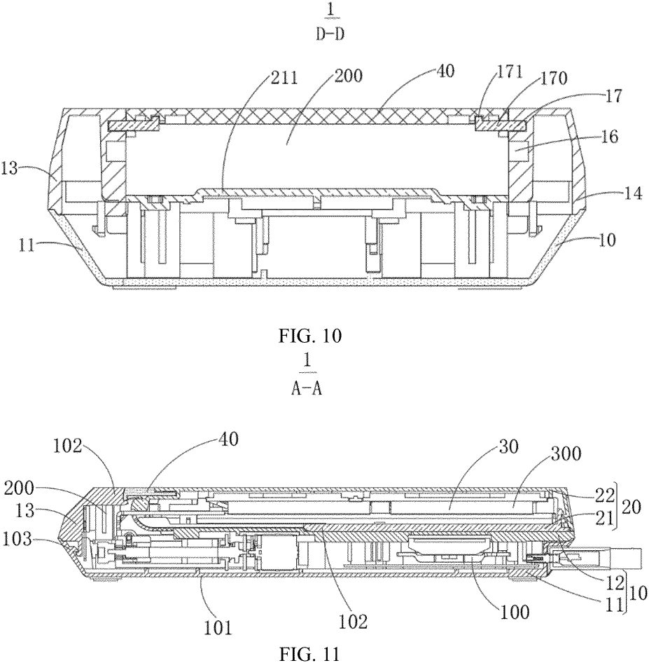

Next, the disclosure will introduce in detail how the holder 40 is connected to the first housing 10 by movement. Specific reference is made to FIGS. 9 and 10. FIG. 9 is an exploded view of a portion of a charging device in another embodiment of the disclosure. FIG. 10 is a schematic cross-sectional view of the charging device in FIG. 1 in another embodiment of the disclosure, taken along line C-C. The side of the first side wall 14 proximal to the second receiving space 130 is further provided with a second rotation groove 17. The charging device 1 further includes a second rotation shaft 170. One end of the second rotation shaft 170 is connected to the holder 40, and the other end of the second rotation shaft 170 is disposed in the second rotation groove 17.

In this embodiment, the second rotation groove 17 can be opened on the first side wall 14. One end of the second rotation shaft 170 is connected to the holder 40, and the other end of the second rotation shaft 170 is disposed in the second rotation groove 17. In this way, the rotation of the second rotation shaft 170 in the second rotation groove 17 can drive the holder 40 to rotate together. For the specific rotation process, reference may be made to the rotation process of the first rotation shaft 160.

In at least one alternative embodiment, a slot 171 is provided on a side of the holder 40 proximal to the first sub-housing 11, and one end of the second rotation shaft 170 is disposed in the slot 171.

In this embodiment, a slot 171 can be provided on the side of the holder 40 proximal to the first sub-housing 11 (that is, the lower side of the holder 40), and one end of the second rotation shaft 170 can be set in the slot 171, thereby one end of the second rotation shaft 170 is connected to the holder 40. Moreover, one end of the second rotation shaft 170 is disposed in the slot 171, which also facilitates the installation of the holder 40 and the second rotation shaft 170. Specifically, the other end of the second rotation shaft 170 can be set in the second rotation groove 17 first, and then the holder 40 can be placed, and then only the second rotation shaft 170 can be rotated, and one end of the second rotation shaft 170 can be automatically snapped into the slot 171, so as to realize the installation.

Referring back to FIG. 2, in this embodiment, when the holder 40 is in the receiving state, the side surface of the holder 40 distal from the first sub-housing 11 and the side surface of the protruding portion 13 distal from the first sub-housing 11 is flush.

When the charging device 1 is in a horizontal state and the holder 40 is in the receiving state (i.e., the holder 40 has not rotated), the side surface of the holder 40 distal from the first sub-housing 11 and the side surface of the protruding portion 13 distal from the first sub-housing 11 is flush with each other. The side surface of the holder 40 distal from the first sub-housing 11 can be understood as the upper surface of the holder 40, and the side surface of the protruding portion 13 distal from the first sub-housing 11 can be understood as the upper surface of the protruding portion 13. Moreover, the side surface of the holder 40 distal from the first sub-housing 11 and the side surface of the protruding portion 13 distal from the first sub-housing 11 can form an abutment surface of the charging device 1 for abutting against the electronic device 2. Therefore, making the surfaces of the above two components flush can improve the flatness of the surface of the charging device 1.

In addition, when the holder 40 is in the receiving state, it can be understood that the holder 40 is accommodated in the first housing 10, which means that the holder 40 is completely disposed in the first housing 10. In other words, the side surface of the holder 40 distal from the first sub-housing 11 is lower than the side surface of the protruding portion 13 distal from the first sub-housing 11. In at least one alternative embodiment, the holder 40 is flush with the first housing 10. In other words, the side surface of the holder 40 distal from the first sub-housing 11 and the side surface of the protruding portion 13 distal from the first sub-housing 11 are flush. Therefore, in this embodiment, the above two positions of the holder 40 can be understood as the receiving state of the holder 40. Specific reference is now made to FIG. 11. FIG. 11 is a schematic cross-sectional view of the charging device in FIG. 1 in another embodiment of the disclosure, taken along line A-A. In this embodiment, the first housing 10 has a first surface 101 and a second surface 102 opposite to each other, and a third surface 103 connecting the first surface 101 and the second surface 102. At least a portion of the second surface 102 may be configured to abut against the second housing 20, and when the holder 40 is in the protruding state, the holder 40 protrudes from the second surface 102 beyond the first housing 10.

In this embodiment, the first housing 10 has a first surface 101, a second surface 102, and a third surface 103. The first surface 101 can be understood as the lower surface of the first housing 10 as shown in FIG. 11, and the second surface 102 can be understood as the upper surface of the first housing 10. Instead, the second surface 102 is composed of the second sub-housing 12 and the protruding portion 13. The third surface 103 can be understood as the side surface of the first housing 10. Similarly, the third surface 103 is not composed of one component, but a third surface 103 composed of the first sub-housing 11 and the protruding portion 13. In this embodiment, when the holder 40 is in the protruding state, the holder 40 can protrude from the second surface 102 to the first housing 10 instead of protruding from the first surface 101 or the third surface 103 on the first housing 10. Since the electronic device 2 is placed on the fourth sub-housing 22 when it is horizontal, the holder 40 protrudes from the second surface 102 of the protruding portion 13 (i.e., the holder 40 protrudes from the upper surface of the protruding portion 13). It is more convenient to make the electronic device 2 abut against the holder 40, thereby simplifying the structure of the charging device 1 and reducing the size of the charging device 1.

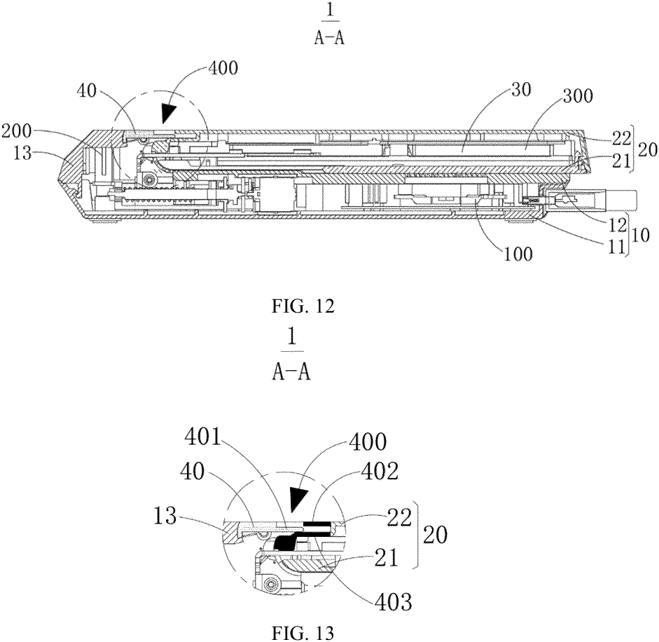

Specific reference is now made to FIG. 12. FIG. 12 is a schematic cross-sectional view of the charging device in FIG. 1 when the charging device is in a rearward state in an embodiment of the disclosure, taken along line A-A. In this embodiment, the holder 40 and the second housing 20 form a clearance space 400, and the clearance space 400 may be configured to allow the second housing 20 to rotate relative to the first housing 10.

In this embodiment, the holder 40 and the second housing 20 can be surrounded to form a clearance space 400, so that the second housing 20 can rotate relative to the first housing 10. It can be understood that, when the second housing 20 rotates, it will move toward the side surface of the holder 40 proximal to the second housing 20. When the charging device 1 is in initial state, the second housing 20 will abut against the side surface of the holder 40, which will affect the rotation of the second housing 20. Therefore, the clearance space 400 is formed to create a certain distance between the second housing 20 and the side surface of the holder 40, so as to facilitate the rotation of the second housing 20.

However, the formation of the clearance space 400 is already formed when the charging device 1 is in the initial state, or in other words, although the charging device 1 does not have the clearance space 400 in the initial state, it is formed during the process of the charging device 1 from the initial state to the rearward state. Both of the scenarios should belong to the scope of this application. In other words, whether the clearance space 400 exists at the beginning or is formed later is not limited in this application.

Next, the disclosure will introduce in detail how the holder 40 directly cooperates with the second housing 20 to perform follow-up rotation. Specific reference is made to FIG. 13, which is a partial schematic diagram of FIG. 12. In this embodiment, at least part of the surface of the holder 40 proximal to the fourth sub-housing 22 is provided with a first rotation portion 401, and at least part of the side surface of the fourth sub-housing 22 proximal to the holder 40 is provided with a second rotation portion 402. The second rotation portion 402 is farther away from the first sub-housing 11 than the first rotation portion 401, and there is a distance between the second rotation portion 402 and the one side surface of the fourth sub-housing 22 proximal to the holder 40. The holder 40, the first rotation portion 401, the fourth sub-housing 22, and the second rotation portion 402 are surrounded to define the clearance space 400.

In this embodiment, a first rotation portion 401 may be provided on the side of the holder 40 proximal to the fourth sub-housing 22, and a second rotation portion 402 may be provided on a part of the surface of the fourth sub-housing 22 proximal to the side of the holder 40, and the second rotation portion 402 is farther away from the first sub-housing 11 than the first rotation portion 401. In other words, the second rotation portion 402 is located above the first rotation portion 401. Finally, the holder 40, the first rotation portion 401, the fourth sub-housing 22, and the second rotation portion 402 surround and form the clearance space 400. When the charging device 1 moves from the rearward state to the vertical state, the second housing 20 will rotate in a direction distal from the first housing 10. For example, the second housing 20 will rotate counterclockwise, so the second rotation portion 402 located above also rotates counterclockwise toward a direction proximal to the first rotation portion 401 (e.g., downward). At this time, the second rotation portion 402 will abut against the first rotation portion 401. When the second housing 20 and the second rotation portion 402 continue to rotate, the second rotation portion 402 will give the first rotation portion 401 a certain rotational force, so the first rotation portion 401 will rotate in the opposite direction along with the second rotation portion 402 rotates. For example, the first rotation portion 401 rotates clockwise, so that the holder 40 moves from the receiving state to the protruding state.

In addition, the distance between the second rotation portion 402 and the first rotation portion 401 affects the timing when the second rotation portion 402 abuts the first rotation portion 401, and also affects the angles between the holder 40 and the second housing 20. For example, when the charging device 1 is in a horizontal state, the second rotation portion 402 has already abutted against the first rotation portion 401. In this way, once the second housing 20 starts to rotate, the second rotation portion 402 will drive the first rotation portion 401 to rotate together. If the charging device 1 is in a horizontal state, there is a certain gap between the second rotation portion 402 and the first rotation portion 401. At this time, when the second housing 20 just starts to rotate, the second rotation portion 402 will not abut against the first rotation portion 401, therefore the first rotation portion 401 remains stationary. When the second rotation portion 402 rotates by a certain angle, the second rotation portion 402 will abut against the first rotation portion 401 to drive the first rotation portion 401 to rotate.

In addition, when the first rotation portion 401 rotates and the side surface of the holder 40 proximal to the fourth sub-housing 22 abuts the second rotation portion 402, the second rotation portion 402 will be resisted and cannot continue to move, resulting in the second housing 20 cannot continue to rotate. Therefore, in this embodiment, the maximum rotation angle of the second housing 20 can also be controlled by controlling the size of the clearance space 400.

With further reference to FIG. 13, in this embodiment, a third rotating portion 403 is provided on the part of the surface of the fourth sub-housing 22 proximal to the holder 40. Compared with the first rotating portion 403, the rotating part 401 is proximal to the first sub-housing 11. When the charging device 1 is in the initial state, the third rotation portion 403 abuts the first rotation portion 401. When the charging device 1 is changing from the rearward state to the vertical state, the third rotation portion 403 is separated from the first rotation portion 401, and when the charging device 1 moves from the vertical state to the rearward state, the third rotation portion 403 can abut against the first rotation portion 401 again and drive the first rotation portion 401 to rotate.

It can be known from the above that the cooperation between the first rotation portion 401 and the second rotation portion 402 can make the holder 40 change from the receiving state to the protruding state when the charging device 1 changes from the horizontal state to the vertical state. However, when the charging device 1 is in the process of changing from the vertical state to the horizontal state, the second rotation portion 402 rotates in the opposite direction (e.g., the second rotation portion 402 rotates clockwise), and at this time the second rotation portion 402 will no longer abut against to the first rotation portion 401, so that the holder 40 cannot be moved from the protruding state to the receiving state.

Therefore, in this embodiment, the third rotation portion 403 may also be provided on a part of the surface of the fourth sub-housing 22 on the side proximal to the holder 40. In other words, a part of the surface proximal to the holder 40 of the fourth sub-housing 22 provides the second rotation portion 402 and another part of the surface proximal to the holder 40 of the fourth sub-housing 22 provides the third rotation portion 403. The third rotation portion 403 is more proximal to the first sub-housing 11 than the first rotation portion 401. In other words, the third rotation portion 403 is located below the first rotation portion 401. In this case, when the charging device 1 in the process from the horizontal state to the vertical state, the third rotation portion 403 rotates in a direction distal from the first rotation portion 401 (e.g., rotates counterclockwise), so the third rotation portion 403 will not affect the movement of the first rotation portion 401. However, when the charging device 1 is in the process of turning from the vertical state to the horizontal state, the first rotation portion 401 rotates clockwise under the drive of the second rotation portion 402, so when the third rotation portion 403 turns, the third rotation portion 403 will abut against the first rotating portion 401 of the holder 40, which is already in the protruding state. When the third rotation portion 403 continues to rotate, the first rotation portion 401 will be rotated, so that the holder 40 is rotated from the protruding state to the receiving state.

In addition, in this embodiment, the third rotation portion 403 is made to abut against the first rotation portion 401, so that the third rotation portion 403 can drive the holder 40 to turn to the position of the holder 40 when the charging device 1 is in a horizontal state, thereby improving the rotation performance of the holder 40, and the smoothness of the surface of the charging device 1 is ensured. In summary, when the charging device 1 is horizontal, a gap between the second rotation portion 402 and the first rotation portion 401 allows for adjustment of the angle between the second housing 20 and the holder 40. The third rotation portion 403 abuts the first rotation portion 401 to ensure that the holder 40 is rotated to the initial position by the rotation of the third rotation portion 403 and to ensure the smoothness of the surface of the charging device 1.

In at least one alternative embodiment, there is a gap between the second rotation portion 402 and the third rotation portion 403, and the gap can be used to accommodate the first rotation portion 401. For example, when the charging device 1 is in an initial state, there is no clearance space 400 formed, and the first rotation portion 401 is disposed in the gap at this time, and the first rotation portion 401 can be accommodated effectively. After the second housing 20 moves, the first rotation portion 401 breaks away from the gap, and surrounds the above-mentioned components to form a clearance space 400.

In at least one alternative embodiment, the side surface of the holder 40 distal from the first sub-housing 11, the side surface of the second rotation portion 402 distal from the first sub-housing 11, and the side surface of the fourth sub-housing 22 distal from the first sub-housing 11 are flush with each other.

On the basis that the side surface of the holder 40 distal from the first sub-housing 11 and the side surface of the protruding portion 13 distal from the first sub-housing 11 are flush, the side surface of the holder 40 distal from the first sub-housing 11, the side surface of the second rotation portion 402 distal from the first sub-housing 11, and the fourth sub-housing 22 distal from the first sub-housing 11 are flush with each other. The above-mentioned surfaces together constitute the abutment surface of the charging device 1, making all the abutting surfaces flush can further improve the flatness of the surface of the charging device 1, so that the user can place the electronic device 2 arbitrarily in a horizontal state.

In at least one alternative embodiment, specific reference is again made to FIG. 2. In this embodiment, the first housing 10 includes a connected first sub-housing 11 and a second sub-housing 12. The first sub-housing 11 and the second sub-housing 12 surround and form a first receiving space 100. The second housing 20 includes a third sub-housing 21 and a fourth sub-housing 22 connected to each other. The third sub-housing 21 is more proximal to the first sub-housing 11 than the fourth sub-housing 22, and the third sub-housing 21 and the fourth sub-housing 22 surround to form a third receiving space 200.

The charging device 1 further includes a motor assembly 50. The motor assembly 50 is arranged in the first receiving space 100. The motor assembly 50 is rotatably connected to the second housing 20, and the motor assembly 50 can drive the second housing 20 rotates relative to the first housing 10.

In this embodiment, in order to allow the second housing 20 to rotate relative to the first housing 10, a motor assembly 50 can be added, so that the motor assembly 50 is arranged in the first receiving space 100 in the first housing 10, and the motor assembly 50 is connected to the second housing 20, so that when the motor assembly 50 starts to work, the motor assembly 50 can drive the second housing 20 to rotate relative to the first housing 10. As for the specific structure of the motor assembly 50, as long as it can drive the second housing 20 to rotate relative to the first housing 10, it should be within the scope of the disclosure. This article will introduce several specific embodiments.

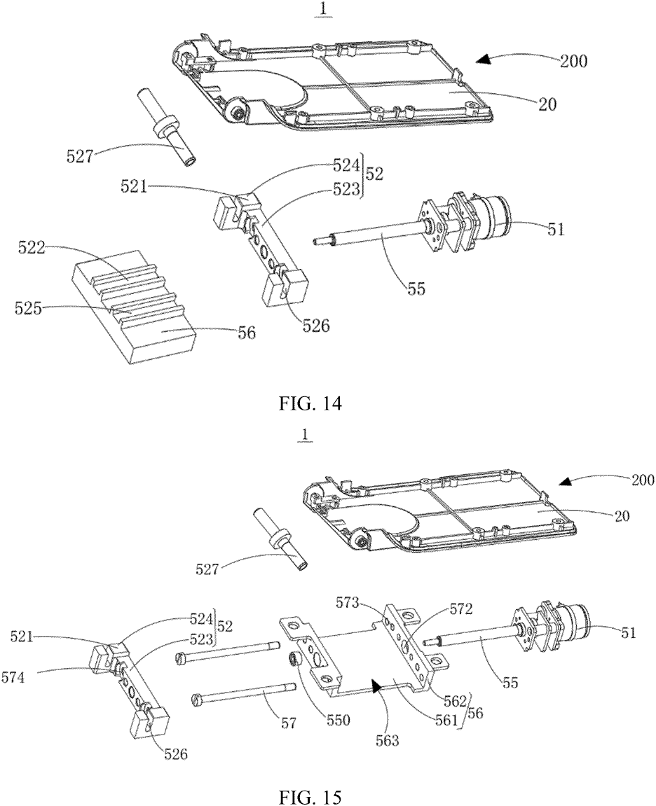

Specific reference is now made to FIGS. 2 and 14. FIG. 14 is an exploded view of a portion of a charging device in another embodiment of the disclosure. In this embodiment, the motor assembly 50 includes a motor 51, a screw rod 55, and a slider 52. The screw rod 55 is connected to the motor 51, the slider 52 is sleeved on the screw rod 55, and the slider 52 is screwed to the screw rod 55. The slider 52 is provided with a first sliding portion 521. The motor assembly 50 also includes a second sliding portion 522, and the first sliding portion 521 and the second sliding portion 522 cooperate with each other so that the slider 52 can slide along the screw rod 55 when the motor 51 operates.

The side of the slider 52 proximal to the second sub-housing 12 is provided with a third rotation groove 526, and the charging device 1 further includes a third rotation shaft 527. One end of the third rotation shaft 527 is connected to the second housing 20, and the other end of the third rotation shaft 527 is disposed in the third rotation groove 526.

In this embodiment, the sliding of the slider 52 can be realized through cooperation of the motor 51, the screw rod 55, and the slider 52. Specifically, the screw rod 55 can be connected to the motor 51, and the slider 52 can be sleeved on the screw rod 55. When operating, the motor 51 can drive the screw rod 55 to rotate together, and then drive the slider 52 to rotate. In addition, in order to make the slider 52 slide instead of rotate, in this embodiment, a first sliding portion 521 can be provided on the slider 52, which cooperates with the second sliding portion 522 connected to the first housing 10 to drive the rotational movement of the slider 52 driven by the screw rod 55 to converted into a sliding movement. It can also be understood that the cooperation between the first sliding portion 521 and the second sliding portion 522 can realize the guiding function, and convert the rotational force of the screw rod 55 into a sliding force, thereby driving the slider 52 to slide.

In at least one alternative embodiment, the slider 52 is provided with a threaded hole, the surface of the screw rod 55 is threaded, and the slider 52 is threadedly connected to the screw rod 55 through the threaded hole. In this embodiment, the slider 52 and the screw rod 55 can be threadedly connected through threaded holes and threads. In addition, since the screw rod 55 and the slider 52 have a certain self-locking property, when the charging device 1 is in a vertical state (i.e., after the second housing 20 is rotated and lifted), the second housing 20 will not fall because the motor 51 will not reverse under the weight of second housing 20 or the weight of the electronic device 2 placed on the second housing 20, or other external impact forces, which improves the safety of the charging device 1.

In addition, a third rotation groove 526 is formed on the side of the slider 52 proximal to the second sub-housing 12. One end of the third rotation shaft 527 is connected to the second housing 20, and the other end of the third rotation shaft 527 is arranged in the third rotation groove 526. In this way, the second housing 20 and the slider 52 can be connected together through the third rotation shaft 527. When the motor 51 operates and drives the slider 52 to slide, the third rotation shaft 527 can drive the second housing 20 to slide relative to the first housing 10 in the first rotation groove 16.

In addition, the third rotation groove 526 is extended toward the direction of the first sub-housing 11. In this embodiment, the third rotation groove 526 can also extend toward the direction of the first housing 10. In this way, when the second housing 20 moves to the end relative to the first housing 10 in the first rotation groove 16 (i.e., when the first rotation shaft 160 abuts the groove wall of the first rotation groove 16), at this time, driven by the motor 51, the slider 52 will still continue to slide, but at this time the second housing 20 cannot continue to slide, so the third rotation shaft 527 will slide in the third rotation groove 526 toward the direction proximal to the first sub-housing 11, and then cooperating with the third rotation shaft 527 to slide along the direction parallel to the first sub-housing 11 driven by the slider 52. The two kinds of motions can be combined to make the second housing 20 rotate relative to the first housing 10.

In summary, the disclosure describes a charging device 1 with a unique structure that can allow a single motor 51 to drive the second housing 20 to translate and rotate relative to the first housing 10. In the process, the charging device 1 can have a horizontal state and a vertical state. In the horizontal state, the second housing 20 is parallel to the first housing 10, while in the vertical state, an angle is formed between the second housing 20 and the first housing 10. The horizontal state includes an initial state and a rearward state. In the initial state, the second rotation portion 402 abuts the side surface of the holder 40 proximal to the fourth sub-housing 22. In the rearward state, the second housing 20 moves relative to the first housing 10 and there is a distance between the second rotation portion 402 and the side surface of the holder 40 proximal to the fourth sub-housing 22. When the charging device 1 moves from the initial state to the rearward state, the motor 51 drives the slider 52 to slide through the screw rod 55, thereby driving the second housing 20 to move relative to the first housing 10. When the charging device 1 is in the rearward state, the first rotation shaft 160 abuts the first side wall 14 to form the groove wall of the first rotation groove 16. When the charging device 1 moves from the rearward state to the vertical state, the slider 52 continues to slide, thereby driving the other end of the third rotation shaft 527 to slide in the direction toward the first sub-housing in the third rotation groove 526, and then drives the second housing 20 to rotate relative to the first housing 10.

As for how the first sliding portion 521 cooperates with the second sliding portion 522 to make the slider 52 slide, this application introduces two embodiment methods: the sliding block 524 cooperates with the sliding groove 525 to guide and the guide rod 57 to guide.

In at least one alternative embodiment, as shown in FIG. 7, the first rotation groove 16 is extended toward the moving direction of the first housing 10 (shown as the direction D3 in FIG. 7). Extending the first rotation groove 16 toward the moving direction of the first housing 10 can make the first rotation shaft 160 move in the first rotation groove 16, thereby driving the second housing 20 to move backward relative to the first housing 10.

Referring back to FIG. 14, in this embodiment, the motor assembly 50 further includes a support member 56. The support member 56 is connected to the first sub-housing 11. One side of the support member 56 distal from the first sub-housing 11 is provided with a sliding groove 525, and the side of the slider 52 proximal to the support member 56 is provided with a sliding block 524. The sliding block 524 can slide in the sliding groove 525.

In the first embodiment provided by the disclosure for coordinating and guiding through the slider 524 and the sliding groove 525, in order to realize the above-mentioned cooperating relationship, in this embodiment, a support member 56 can be added on the first sub-housing 11, and the second sliding portion 522 is disposed on a side of the support member 56 distal from the bottom wall 211. It can also be understood that the support member 56 and the first sub-housing 11 are a split structure. The second sliding portion 522 is arranged on the support member 56, and then the support member 56 is arranged on the first sub-housing 11, which can reduce the difficulty in manufacturing the first sub-housing 11.

In addition, the slider 52 includes a connection portion 523 and sliders 524 protruding from opposite ends of the connection portion 523. The connection portion 523 sleeves the screw rod 55, and the one side of the support member 56 distal from the first sub-housing 11 is provided with a sliding groove 525. The sliding block 524 cooperates with the sliding groove 525 to allow the slider 52 to slide.

Based on the support member 56, the slider 52 includes a connection portion 523 and sliding blocks 524 protruding from opposite ends of the connection portion 523. In this embodiment, the sliding block 524 can be split into two parts, and the connection portion 523 may be configured to sheath the screw rod 55, while the sliding block 524 is the first sliding portion 521. In addition, a sliding groove 525 is provided on a side of the support member 56 distal from the first sub-housing 11, and the sliding groove 525 is the second sliding portion 522. In this embodiment, the rotation of the slider 52 can be transformed into sliding through the cooperation of the sliding block 524 and the sliding groove 525, and the sliding block 524 can slide directionally in the sliding groove 525.

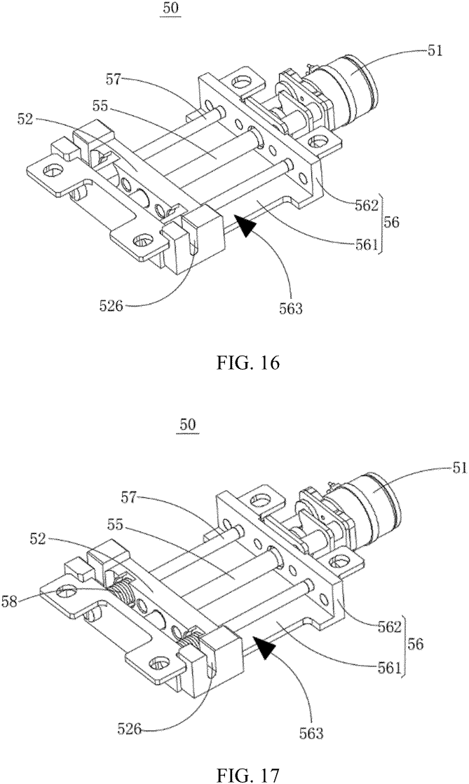

Specific reference is made to FIGS. 2, 15, and 16. FIG. 15 is an exploded view of a portion of a charging device in another embodiment of the disclosure. FIG. 16 is a schematic structural view of a motor assembly in an embodiment of the disclosure. In this embodiment, the motor assembly 50 further includes a support member 56 and a guide rod 57. The support member 56 includes a bottom plate 561 and side plates 562 bent and connected to opposite ends of the bottom plate 561. The bottom plate 561 is surrounded by the side plate 562 to form a sliding space 563. The slider 52 is set in the sliding space 563. The second through hole 572 is opened on the side plate 562. The screw rod 55 passes through the second through hole 572 and the slider 52. The third through hole 573 is also opened on the side plate 562. The fourth through hole 574 is opened on the slider 52. The guide rod 57 is connected to the side plate 562. The guide rod 57 passes through the third through hole 573 and the fourth through hole 574. The slider 52 can slide along the guide rod 57 through the fourth through hole 574.

A second embodiment of the present disclosure provides for another mode of guiding via guide rod 57. In this embodiment, the support member 56 and the guide rod 57 may also be added. In the support member 56 of this embodiment, the support member 56 includes a bottom plate 561 and a side plate 562, and the bottom plate 561 and the side plates 562 can surround and form a sliding space 563, so that the slider 52 can slide in the sliding space 563. In addition, the side plate 562 defines a second through hole 572, and the screw rod 55 passes through the second through hole 572 and the threaded hole of the slider 52, so that the screw rod 55 is mounted on the side plate 562. A third through hole 573 is defined in the side plate 562, a fourth through hole 574 is defined in the slider 52, and the guide rod 57 passes through the third through hole 573 and the fourth through hole 574 and is connected to the side plate 562. In this way, the slider 52 can convert the rotation of the slider 52 into sliding under the guidance of the guide rod 57, and slide along the axial direction of the screw rod 55.

In at least one alternative embodiment, the number of guide rods 57 may be one or multiple. In this embodiment, the number of guide rods 57 is two for illustration.

In at least one alternative embodiment, the motor 51 and the support member 56 can be fixedly connected by screws, and the guide rod 57 is fixedly connected to the threaded hole at the end of the support member 56 through the thread at its end. In at least one alternative embodiment, a second bearing 550 is also provided in the first through hole 213, and the second bearing 550 is sleeved on the end of the screw rod 55, and the second bearing 550 can cooperate with the screw rod 55 and the support member 56 to improve the rotational performance of the screw rod 55. Further reference is made to FIG. 17. FIG. 17 is a schematic structural view of a motor assembly in another embodiment of the disclosure. In this embodiment, the motor assembly 50 further includes an elastic member 58, the elastic member 58 is arranged in the sliding space 563, the elastic member 58 is sleeved on the guide rod 57, and the elastic member 58 is arranged between the side plate 562 and the slider 52. When the charging device 1 is in the initial state, the elastic member 58 abuts the side plate 562 and the slider 52, and the elastic member 58 is in compression state.

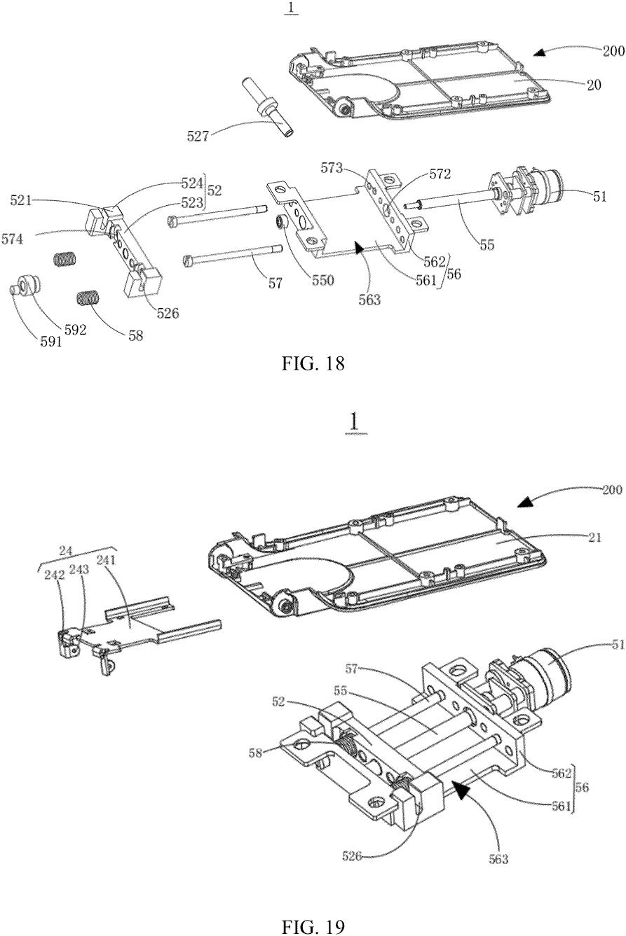

In this embodiment, the motor assembly 50 can further include an elastic member 58, so that the elastic member 58 is sheathed on the guide rod 57, and the elastic member 58 is disposed between the side plate 562 and the slider 52. When the charging device 1 is in the initial state (i.e., when the motor 51 of the charging device 1 does not start to work, or when the motor 51 has stopped working), the elastic member 58 abuts the side plate 562 and the slider 52, and the elastic member 58 is in a compressed state. In this way, when the charging device 1 starts to work, the elastic member 58 will give the slider 52 an elastic restoring force towards the direction of the motor 51, so that the slider 52 is more likely to slide towards the direction of the motor 51, and then it is easier to rotate and lift the second housing 20 at the initial stage, further improves the rotation performance of the second housing 20. In at least one alternative embodiment, the elastic member 58 includes but is not limited to a spring. Specific reference is now made to FIGS. 2 and 18. FIG. 18 is an exploded view of a portion of a charging device in another embodiment of the disclosure. In this embodiment, the charging device 1 further includes a distance sensor 62, the distance sensor 62 includes a Hall magnet 591 and a Hall support member 592, and the Hall magnet 591 is installed in the Hall support member 592, the Hall support member 592 is sheathed on the end of the screw rod 55 distal from the motor 51.

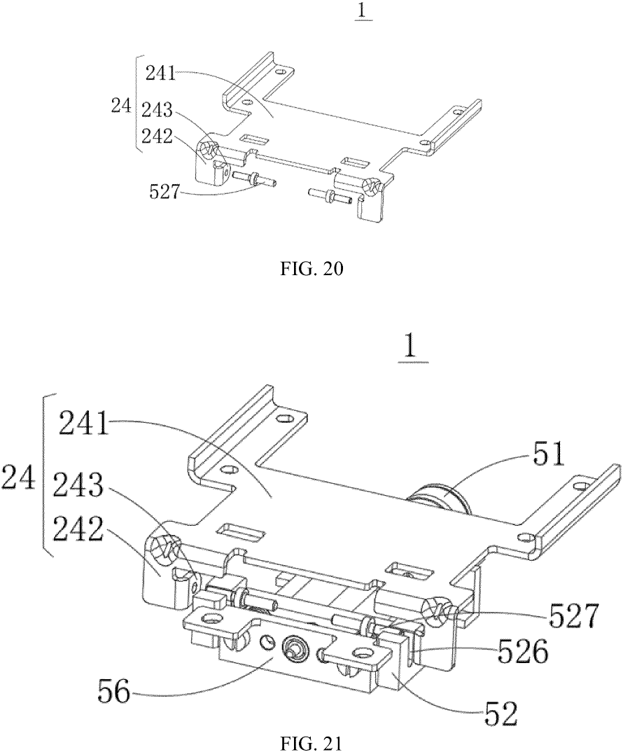

In this embodiment, a distance sensor 62 can also be added. The distance sensor 62 can be used to detect the motion state of the motor assembly 50. Specifically, the distance sensor 62 can detect the sliding distance of the slider 52. If the sliding distance of the slider 52 is too large, the motor assembly 50 can be stopped to prevent the charging device 1 from being damaged. Hence, through the cooperation of the distance sensor 62 and the motor assembly 50, the motion state of the motor assembly 50 can be effectively controlled, and the motor assembly 50 can be protected from damage. Specific reference is now made to FIGS. 2 and 19-21. FIG. 19 is an exploded view of a portion of a charging device in another embodiment of the disclosure. FIG. 20 is a schematic structural view of a connection member and a third rotation shaft in an embodiment of the disclosure. FIG. 21 is a schematic structural view of the cooperation structure of the connection member, the third rotation shaft, and the motor assembly in an embodiment of the disclosure. In this embodiment, the first housing 10 further includes a protruding portion 13 provided on the side of the second sub-housing 12 facing away from the first sub-housing 11. The protruding portion 13 includes two first side walls 14 oppositely arranged, and a second side wall 15 connected between the two first side walls 14. The first side walls 14 and the second side wall 15 surround to form a second housing space 130, and the second receiving space 130 is connected to the first receiving space 100.

The second housing 20 also includes a connection member 24. The connection member 24 includes a first connection portion 241, a second connection portion 242, and a third connection portion 243. Part of the first connection portion 241 is arranged in the third receiving space 200, and the first connection portion 241 is connected to the third sub-housing 21. The second connection portion 242 is bent and connected to the first connection portion 241, and the second connection portion 242 penetrates through the second receiving space 130 and is arranged in the first receiving space 100. The third connection portion 243 is bent and connected to the second connection portion 242, and the third connection portion 243 is arranged in the first receiving space 100. One end of the third rotation shaft 527 is connected to the third connection portion 243.

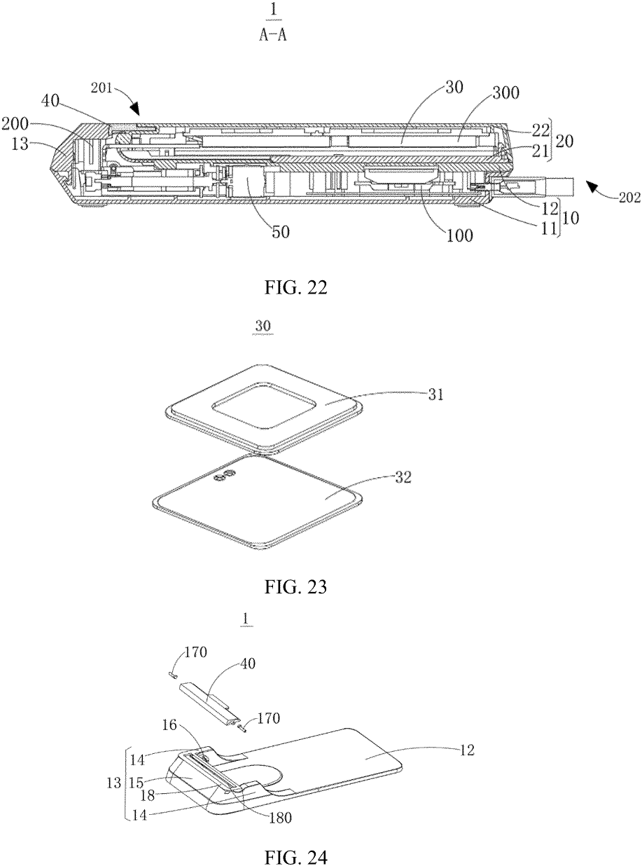

In this embodiment, one end of the third rotation shaft 527 is not directly connected to the second housing 20. The second housing 20 further includes a connection member 24, and the connection member 24 includes a first connection portion 241, a second connection portion 242, and a third connection portion 243, so that at least part of the first connection portion 241 is disposed in the third receiving space 200, and connected to the third sub-housing 21. Then the second connection portion 242 is bent and connected to the first connection portion 241, and the second connection portion 242 passes through the second receiving space 130 to reach the first receiving space 100. Finally, one end of the third rotation shaft 527 is connected to the third connection portion 243 which is bent and connected to the second connection portion 242. It can also be understood that the third sub-housing 21, the fourth sub-housing 22, the first connection member 24, and the connection member 24 are all split structures. The second housing 20 of the disclosure can be obtained only by preparing the above four structural parts respectively, and then assembling, thereby reducing the difficulty of preparation of the second housing 20. Specific reference is now made to FIG. 22. FIG. 22 is a schematic cross-sectional view of the charging device in FIG. 1 in another embodiment of the disclosure, taken along line A-A. In this embodiment, the second housing 20 includes a first end and a second end opposite to each other, the first end is closer to the holder 40 than the second end, and the motor assembly 50 is rotatably connected at the first end.

In this embodiment, the first end and the second end can be understood as, when the second housing 20 rotates, the first end will rotate toward the direction proximal to the first sub-housing 11, and the second end will rotate toward the direction distal from the first sub-housing 11. In this embodiment, the motor assembly 50 is connected to the first end. When the second housing 20 is rotated, the connection between the second housing 20 and the motor assembly 50 will not be exposed, but will be covered by the third sub-housing 21, thereby improving the appearance performance of the charging device 1.

In addition, it can be seen from the above content that the motor assembly 50 can drive the second housing 20 to rotate relative to the first housing 10 during operation.

In this embodiment, before the motor assembly 50 drives the second housing 20 to rotate relative to the first housing 10, the motor assembly 50 may also drive the second housing 20 to move relative to the first housing 10 to form the clearance space 400. It can also be understood that the motor assembly 50 can not only drive the second housing 20 to rotate relative to the first housing 10, but the motor assembly 50 can also drive the second housing 20 to move relative to the first housing 10. In this case, the clearance space 400 can be formed by making the motor assembly 50 drive the second housing 20 to move relative to the first housing 10. In other words, the charging device 1 does not form the clearance space 400 in the initial state, and the clearance space 400 is formed after the motor assembly 50 drives the second housing 20 to move relative to the first housing 10. The formation of the clearance space 400 was previously explained in detail and will not be repeated here. In this embodiment, the clearance space 400 is formed later to reduce the gap on the surface of the charging device 1 in its initial state. This can improve the sealing performance and appearance of the charging device 1.

Specific reference is made to FIGS. 5 and 23. FIG. 23 is an exploded view of the charging assembly in an embodiment of the disclosure. In this embodiment, the charging assembly 30 is disposed in the third receiving space 200. The charging assembly 30 includes a charging coil 31 and a heat dissipation bracket 32, and the charging coil 31 is disposed on the heat dissipation bracket 32.

In this embodiment, the second housing 20 has a third receiving space 200 inside, and the charging assembly 30 is disposed in the third receiving space 200. The charging assembly 30 may include a charging coil 31 and a heat dissipation bracket 32. The charging coil 31 is mainly used as a structural member for charging the electronic device assembly 3, and the heat dissipation bracket 32 may be configured to carry the charging coil 31 and dissipate heat for the charging coil 31, so as to discharge the heat generated by the charging coil 31 in time, and to improve the heat dissipation performance of the charging coil 31.

The above content introduces the new technology formed when the second housing 20 can rotate relative to the first housing 10, the second housing 20 is directly matched with the holder 40, and the holder 40 is rotationally connected to the first housing 10. In addition to the above combined new technical solutions, this application also provides another new technical solution: for example, when the second housing 20 can rotate relative to the first housing 10, the second housing 20 can 70 and the holder 40 are indirectly matched, and the holder 40 is connected to the first housing 10 in a new technical solution: the charging device 1 also includes a transmission member 70, when the second housing 20 rotates relatively to the first housing 10, the second housing 20 drives the transmission member 70 to rotate and then drives the holder 40 to rotate. Next, this application will introduce in detail the specific structure of the charging device 1 that can achieve the above purpose.

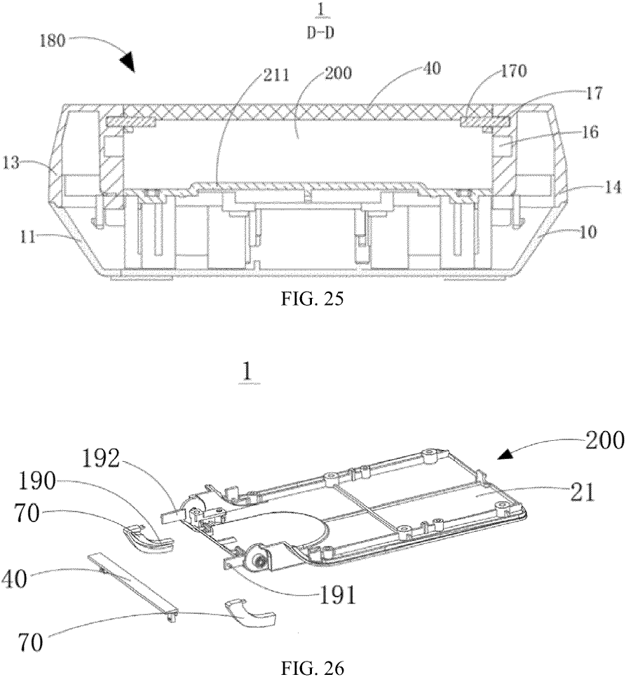

The structures of the first housing 10 and the second housing 20 in this technical solution are the same as those of the previous technical solution, and the disclosure will not repeat them here. However, for the matching relationship between the holder 40 and the first housing 10, this technical solution also provides another structure. Specific reference is now made to FIGS. 24 and 25. FIG. 24 is an exploded view of a portion of a charging device in another embodiment of the disclosure. FIG. 25 is a schematic cross-sectional view of the charging device in FIG. 1 in another embodiment of the disclosure, taken along line D-D. In this embodiment, the protruding portion 13 further includes a top wall 18. The top wall 18 connects the two first side walls 14 and the second side wall 15. The two first side walls 14, the second side wall 15 and the top wall 18 surround and form the second receiving space 130. The top wall 18 is provided with a fifth through hole 180, and the fifth through hole 180 communicates with the second receiving space 130. The hole wall of the top wall 18 provided with the fifth through hole 180 is provided with a second rotation groove 17. The charging device 1 also includes a second rotation shaft 170. At least part of the holder 40 is arranged in the fifth through hole 180. One end of the second rotation shaft 170 is connected to the holder 40, and the other end of the second rotation shaft 170 is disposed in the second rotation groove 17.

In the second embodiment mode provided by the disclosure, the protruding portion 13 further includes a top wall 18. The first side walls 14, the second side wall 15, and the top wall 18 surround and form the second receiving space 130, and a fifth through hole 180 communicating with the second receiving space 130 can be opened on the top wall 18. The partial holder 40 of this embodiment can be disposed in the fifth through hole 180, and the second rotation groove 17 is defined on the wall of the fifth through hole 180. In addition, one end of the second rotation shaft 170 can be connected to the holder 40, and the other end of the second rotation shaft 170 is arranged in the second rotation groove 17, and the second rotation shaft 170 cooperates with the second rotation groove 17 to make the holder 40 rotate in the fifth through hole 180. In this embodiment, the second rotation shaft 170 is set in the fifth through hole 180. In other words, a part of the top wall 18 is also provided between the second housing 20 and the holder 40, so that the holder 40 can be effectively protected by this part of the top wall 18, and to avoid the second housing 20 colliding with the holder 40 when rotating.

In at least one alternative embodiment, when the charging device is in an vertical state, the holder 40 can be made perpendicular to the second housing 20, so as to further improve the effect of limiting the electronic device 2.

In at least one alternative embodiment, the charging device 1 further includes an anti-slip member, and the anti-slip member is provided on a side of the holder 40 distal from the first sub-housing 11. In this embodiment, an anti-slip member can also be added, so that the anti-slip member is arranged on the side of the holder 40 distal from the first sub-housing 11, which can also be understood as that the anti-slip member is arranged on the upper side of the first sub-housing 11. The high friction coefficient and anti-slip performance of the anti-slip members can be used to further improve the position-limiting effect of the holder 40 for position-limiting the electronic device 2.

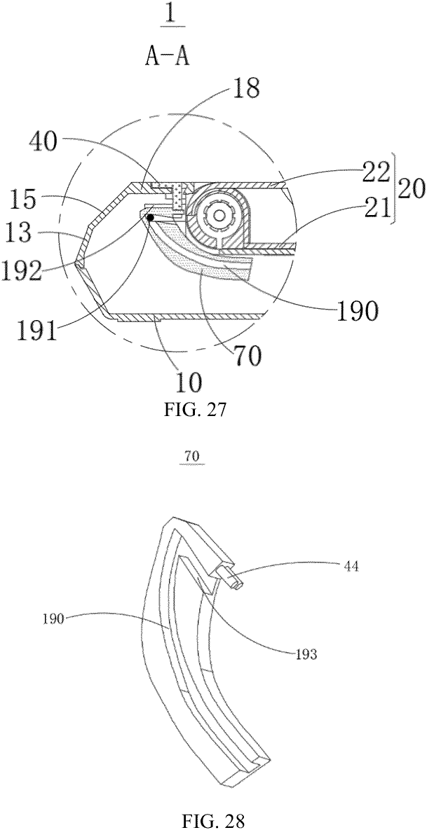

Next, the cooperation relationship between the transmission member 70 and the holder 40 and the second housing 20 will be described in detail. Specific reference is now made to FIGS. 26 to 28. FIG. 26 is an exploded view of a third sub-housing, a transmission member, and a holder in an embodiment of the disclosure. FIG. 27 is a schematic partial cross-sectional view of a charging device in an embodiment of the disclosure. FIG. 28 is a schematic perspective view of a transmission member in an embodiment of the disclosure. In this embodiment, at least part of the transmission member 70 is arranged in the second receiving space 130, the transmission member 70 is connected to the holder 40, and the transmission member 70 is provided with a fourth rotation groove 190. The charging device 1 also includes a rotation frame 192 and a fourth rotation shaft 191. The rotation frame 192 is connected to the side of the second housing 20 proximal to the holder 40. One end of the fourth rotation shaft 191 is connected to the rotation frame 192, and the opposite end of the fourth rotation shaft 191 is disposed in the fourth rotation groove 190.

In this embodiment, part of the transmission member 70 is arranged in the second receiving space 130, and part of the second transmission member 70 is arranged in the first receiving space 100. The transmission member 70 can be connected to the holder 40, and the transmission member 70 is provided with the fourth rotation groove 190.

In addition, the rotation frame 192 is connected to the side of the second housing 20 proximal to the holder 40, and the rotation frame 192 and the second housing 20 may be of an integrated structure or may be of a separate structure. In this embodiment, the rotation frame 192 and the second housing 20 are shown as an integral structure. It can also be understood that the rotation frame 192 protrudes from the side surface of the second housing 20 proximal to the holder 40. In at least one alternative embodiment, the rotation frame 192 can be connected to the third sub-housing 21.

In this embodiment, a fourth rotation shaft 191 can also be added, so that one end of the fourth rotation shaft 191 is connected to the rotation frame 192, and the other end of the fourth rotation shaft 191 is arranged in the fourth rotation groove 190. In this way, when the second housing 20 rotates, it can drive the rotation frame 192 to rotate, and then drive the fourth rotation shaft 191 to rotate in the fourth rotation groove 190. When the fourth rotation shaft 191 rotates in the fourth rotation groove 190, the transmission member 70 will be subjected to the force of the fourth rotation shaft 191, so that the transmission member 70 will rotate in the direction opposite to the rotation direction of the fourth rotation shaft 191, thereby driving the holder 40 also rotates in a direction opposite to the rotation direction of the fourth rotation shaft 191, and finally the holder 40 is switched between the protruding state and the receiving state.

In at least one alternative embodiment, there are two rotating frames 192, two transmission members 70, and two fourth rotating shafts 191, and they are arranged symmetrically along the second housing 20, so that the rotation uniformity and stability of the second housing 20 can be improved. Specific reference is now made to FIG. 29. FIG. 29 is a schematic perspective structural view of a transmission member and a holder in an embodiment of the disclosure. In this embodiment, one end of the holder 40 proximal to the first sub-housing 11 is provided with a fixing hole 43. The transmission member 70 is provided with a connecting rod shaft 44, and the connecting rod shaft 44 is arranged on the fixing hole 43.

The above content mentions that the transmission member 70 can be connected to the holder 40. In this embodiment, a fixing hole 43 can be provided at the end of the holder 40 proximal to the first sub-housing 11, and a connecting rod shaft 44 is arranged on the transmission member 70 so that the connecting rod shaft 44 is set in the fixing hole 43, the transmission member 70 is plugged into the holder 40, which facilitates the installation and disassembly of the holder 40 and the transmission member 70.

Referring back to FIG. 28, in this embodiment, the shape of the fourth rotation groove 190 is arc-shaped, and the fourth rotation groove 190 protrudes toward the direction of the first sub-housing 1.

In this embodiment, the movement of the transmission member 70 depends on the rotation of the fourth rotation shaft 191. Since the track of the movement of the fourth rotation shaft 191 is arc-shaped, the shape of the fourth rotation groove 190 is also designed to be arc-shaped in this embodiment, the fourth rotation shaft 191 can be easily rotated in the fourth rotation groove 190. In addition, in this embodiment, the fourth rotation groove 190 can protrude toward the direction of the first sub-housing 11, so that the fourth rotation shaft 191 can drive the transmission member 70 to rotate more easily. In at least one alternative embodiment, the disclosure can change the rotation speed of the transmission member 70 by designing the shape of the fourth rotation groove 190.

Further reference is made to FIGS. 2 and 28. In this embodiment, the extending direction of the fourth rotation groove 190 is parallel to the rotating direction of the fourth rotation shaft 191.

In this embodiment, the extension direction of the fourth rotation groove 190 can be parallel to the rotation direction of the fourth rotation shaft 191, so that the fourth rotation shaft 191 acts more evenly on the transmission member 70 when the fourth rotation shaft 191 rotates, so that the uniformity is further improved when the transmission member 70 rotates.

Referring back to FIG. 28, in this embodiment, the transmission member 70 is provided with an installation groove 193 on a side proximal to the second housing 20, and the installation groove 193 communicates with the fourth rotation groove 190.

In this embodiment, an installation groove 193 communicating with the fourth rotation groove 190 can also be added. The installation groove 193 is opened on the side surface of the transmission member 70 proximal to the second housing 20, so as to facilitate the installation of the fourth rotation shaft 191, such as the fourth rotation shaft 191 can enter the installation groove 193 from the side surface of the second transmission member 70 proximal to the second housing 20, and then enter the fourth rotation groove 190 from the installation groove 193 to wait for the rotation of the second housing 20.

In at least one alternative embodiment, the transmission member 70 is provided with the fourth rotation groove 190 on the side distal from the first side wall 14, and one end of the fourth rotation shaft 191 is connected to one side of the rotation frame 192 proximal to the first side wall 14. In this embodiment, the fourth rotation groove 190 can be opened on the side of the transmission member 70 distal from the first side wall 14, and the fourth rotation shaft 191 is connected to the side of the rotation frame 192 proximal to the first side wall 14, thereby reducing the difficulty of matching between the member 70 and the fourth rotation shaft 191.

In addition, in this embodiment, the charging device 1 may also include a motor assembly 50. At least part of the motor assembly 50 is disposed in the first receiving space 100. The motor assembly 50 is connected to the second housing 20, and the motor assembly 50 may be configured to drive the second housing 20 to rotate relative to the first housing 10.

In this embodiment, in order to allow the second housing 20 to rotate relative to the first housing 10, a motor assembly 50 can be added, so that the motor assembly 50 is arranged in the first receiving space 100 in the first housing 10, and the motor assembly 50 is connected to the second housing 20, so that when the motor assembly 50 starts to work, the motor assembly 50 can drive the second housing 20 to rotate relative to the first housing 10. The specific structure of the motor assembly 50 can be adopted as provided in the disclosure. Other structural forms of the motor assembly 50 can also be used as long as it can drive the second housing 20 to rotate relative to the first housing 10. All such technologies fall within the scope of this disclosure and will not be repeated here.

The above describes the main components of the charging device 1, which can solve various technical problems outlined in this disclosure. Next, a movement process of the charging device 1 is described according to embodiments of the present disclosure.

When the charging device 1 changes from the horizontal state to the vertical state, it is the process of changing from FIG. 2 to FIG. 4, and it can also be understood as the process of the holder 40 from the receiving state to the protruding state. Specifically, the holder 40 is located in the first housing 10 when the motor assembly 50 is not in operation. The motor assembly 50 starts to work to drive the second housing 20 to rotate counterclockwise relative to the first housing 10, and the rotation of the second housing 20 can drive the fourth rotation shaft 191 rotates counterclockwise in the fourth rotation groove 190 of the transmission member 70 through the rotation frame 192, then drives the transmission member 70 to rotate clockwise in a direction opposite to the rotation direction of the fourth rotation shaft 191. The rotation of the transmission member 70 further drives the holder 40 to rotate clockwise, and finally a part of the holder 40 rotates and protrudes from the first housing 10, and forms a positioning groove 41 around the rotated second housing 20 to hold the electronic device 2.

When the charging device 1 changes from the vertical state to the horizontal state, it is the transition process from FIG. 4 to FIG. 2, and it can also be understood as the process of the holder 40 from the protruding state to the receiving state. Specifically, when the motor assembly 50 starts to work, part of the holder 40 protrudes outside the first housing 10. The motor assembly 50 starts to work and drives the second housing 20 to rotate clockwise relative to the first housing 10, the rotation of the second housing 20 can drive the fourth rotation shaft 191 to rotate clockwise in the fourth rotation groove 190 of the transmission member 70 through the rotation frame 192, and then drive the transmission member 70 to rotate counterclockwise in a direction opposite to the rotation direction of the fourth rotation shaft 191. The rotation of the transmission member 70 further drives the holder 40 to rotate counterclockwise, and finally the holder 40 rotates and is received in the first housing 10.

In addition, in addition to the two combined new technical solutions introduced above, this application provides a third technical solution. When the second housing 20 can translate and rotate relative to the first housing 10, the second housing 20 indirectly cooperates with the holder 40 through the transmission member 70, and the holder 40 is combined with the first housing 10 when it is moved and connected. The specific solution is as follows: the charging device 1 further includes a transmission member 70, and the transmission member 70 is detachably connected to the second housing 20 and the holder 40. When the moving distance of the second housing 20 relative to the first housing 10 is less than a preset value, there is a gap between the transmission member 70 and the holder 40; when the moving distance of the second housing 20 relative to the first housing 10 is the preset value, the second housing 20 drives the transmission member 70 to connect to the holder 40. When the moving distance of the second housing 20 relative to the first housing 10 is greater than the preset value, the second housing 20 drives the transmission member 70 to move and then drives the holder 40 to move. In at least one alternative embodiment, when the second housing 20 rotates relative to the first housing 10, the second housing 20 and the transmission member 70 are separated from each other. However, the disclosure does not limit the specific content of the above-mentioned technical solutions, as long as the structure of the charging device 1 that can satisfy the above-mentioned functions should be within the scope of the disclosure.

It can be seen from the above content that the above content mainly introduces three technical solutions that can realize the movement of the holder 40 following the movement of the second housing 20, and introduces in detail the specific structure of the charging device 1 involved in the two technical solutions. Next, this application will continue to discuss the charging device 1 of this application from other dimensions.

Referring to FIGS. 1 to 29, this embodiment provides a charging device 1, including a first housing 10, a second housing 20, the second housing 20 is connected to the first housing 10, and the second housing 20 can translate and rotate relative to the first housing 10, the second housing 20 may be configured to receive an electronic device 2; a charging assembly, the charging assembly is arranged in the second housing and is used for charging the electronic device; and a motor assembly, the motor assembly may be configured to receive a first control signal, and start working under the control of the first control signal, and then drive the second housing to translate and rotate relative to the first housing; the motor assembly may be further configured to receive a second control signal, and stop working under the control of the second control signal.

In this embodiment, the charging device 1 is introduced from another perspective of the charging device 1. The motor assembly 50 may be configured to drive the second housing 20 to translate and rotate relative to the first housing 10, and to lift the second housing 20, so that the charging device 1 can switch between a horizontal state and a vertical state. However, the motor assembly 50 cannot work all the time. It can also be understood that the second housing 20 cannot rotate all the time, but can only rotate within the range allowed by the charging device 1 itself, or within the range allowed by the user. The motor assembly 50 can start working by receiving the first control signal, and can also stop the motor assembly 50 by receiving the second control signal. Therefore, the charging device 1 provided in the disclosure can realize more precise control over the motor assembly 50, and improve the accuracy and stability of the movement of the second housing 20 relative to the first housing 10. In addition, the specific structure of the charging device 1 in this embodiment may be the structure in any of the embodiments provided in FIGS. 1 to 29, and details will not be repeated here in this embodiment.

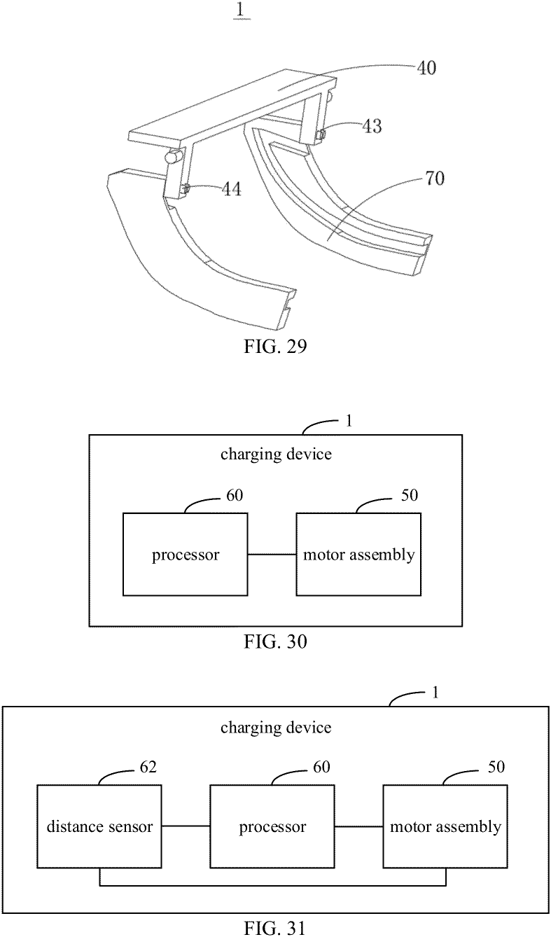

Regarding the first control signal and the second control signal received by the motor assembly 50, the disclosure provides two specific embodiment manners. Specific reference is made to FIG. 30. FIG. 30 is a schematic view of the electronic structure of a charging device in an embodiment of the disclosure. In this embodiment, the charging device 1 further includes a processor 60. The processor 60 is electrically connected to the motor assembly 50, and the processor 60 may be configured to send the first control signal and the second control signal.

In an embodiment manner provided in the disclosure, the first control signal and the second control signal may be sent by the processor 60, and the processor 60 may be configured to more precisely control the movement of the motor assembly 50. Specific reference is made to FIG. 31. FIG. 31 is a schematic view of the electronic structure of the charging device in another embodiment of the disclosure. In this embodiment, the motor assembly 50 includes a motor 51 and a slider 52. The motor 51 may be configured to drive the slider 52 to slide, thereby driving the second housing 20 translate and rotate relative to the first housing 10. The charging device 1 also includes a distance sensor 62. The distance sensor 62 is electrically connected to the processor 60. The distance sensor 62 may be configured to detect the sliding distance of the slider 52. When the sliding distance of the slider 52 is greater than or equal to the preset distance, the processor 60 is configured to send the second control signal.

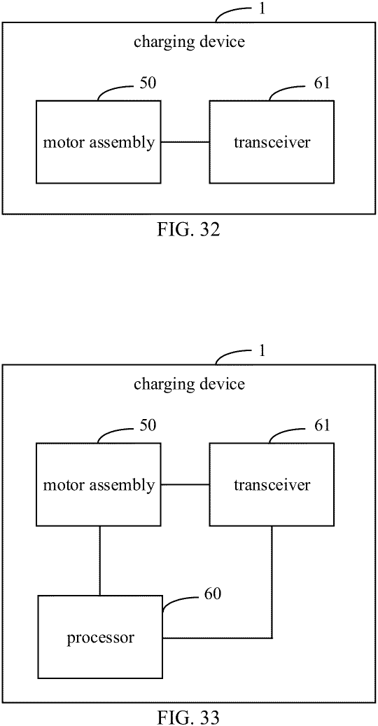

In this embodiment, a distance sensor 62 can be added, and the distance sensor 62 can be used to detect the motion state of the motor assembly 50. When the distance sensor 62 detects that the sliding distance of the slider 52 is greater than or equal to the preset distance, the distance sensor 62 cooperates with the processor 60 so that the processor 60 sends the second control signal to the motor 51 to stop the motor 51 operation, thereby further improving the safety of the charging device 1. Specific reference is made to FIG. 32. FIG. 32 is a schematic view of the electronic structure of the charging device in another embodiment of the disclosure In this embodiment, the charging device 1 further includes a transceiver 61. The transceiver 61 is electrically connected to the motor assembly 50, and the transceiver 61 may be configured to receive the first control signal and the second control signal sent from the terminal.

In another embodiment provided in this application, the transceiver 61 may receive the first control signal and the second control signal sent from the terminal. The terminal may be an external device such as a mobile phone, a computer, or a server. Then the transceiver 61 can directly send the first control signal and the second control signal to the motor assembly 50, thereby increasing the transmission speed of the first control signal and the second control signal, and making the control process of the charging device 1 more rapid and smooth. In at least one alternative embodiment, the transceiver 61 is configured to operate under various wireless communication protocols, including but not limited to Wi-Fi, Bluetooth, or NFC and so on. Specific reference is made to FIG. 33. FIG. 33 is a schematic view of the electronic structure of the charging device in another embodiment of the disclosure. In this embodiment, the charging device 1 further includes a processor 60. The processor 60 is electrically connected to the transceiver 61 and the motor assembly 50, and the transceiver 61 may be further configured to receive the fourth control signal. The transceiver 61 may be further configured to send the fourth control signal to the processor 60, and the processor 60 may be further configured to control the motor assembly 50 to start operating or stop operating according to the fourth control signal.

In this embodiment, a transceiver 61 and a processor 60 may also be added in the first receiving space 100, so that the processor 60 is electrically connected to the transceiver 61. The transceiver 61 is configured to receive a fourth control signal from the terminal. The terminal can be an external device such as a mobile phone, a computer, or a server. These devices send fourth control signals to be received by the transceiver 61. The transceiver 61 then sends the fourth control signal to the processor 60, and the processor 60 can control the operating state of the motor assembly 50 according to the fourth control signal, thereby controlling the overall motion state of the charging device 1, so as to control the charging device 1 at any time. In at least one alternative embodiment, the transceiver 61 is configured to operate under various wireless communication protocols, including but is not limited to Wi-Fi, Bluetooth, or NFC and the like.

In at least one alternative embodiment, reference is again made to FIG. 5. In this embodiment, the charging device 1 further includes a main board 80 and a secondary board 81. The secondary board 81 may be electrically connected to the main board 80, and the processor 60 is arranged on the main board 80. When the motor assembly 50 starts to operate, the distance sensor 62 sends a distance signal to the processor 60 on the main board 80 via the secondary board 81, and the processor 60 may be further configured to obtain the sliding distance of the slider 52 according to the distance signal.

In this embodiment, the processor 60 can be installed on the main board 80, and when the motor assembly 50 starts to operate, the distance sensor 62 may be configured to detect the motion state of the motor assembly 50 (i.e., the sliding distance of the slider 52), to get the distance signal. The distance sensor 62 does not directly send the distance signal to the processor 60, but the distance sensor 62 sends the distance signal to the processor 60 on the main board 80 via the secondary board 81, and utilizes the secondary board 81 to perform a certain processing operation adjustment on the distance signal. After the processor 60 receives the distance signal, the processor 60 can obtain the sliding distance of the slider 52 according to the distance signal. The processor 60 can also obtain the rotation angle of the second housing 20 relative to the first housing 10 according to the distance signal.

In addition, the processor 60 can also determine the relationship between the rotation angle of the second housing 20 and the preset angle. The preset angle can be the information stored in the charging device 1 in advance, or the information obtained by the charging device 1 from the outside in real time, for example, the preset angle can be the information transmitted to the charging device 1 by the user. The preset angle can be understood as the maximum angle that the charging device 1 allows the second housing 20 to rotate, or the preset angle can also be understood as the angle that the user wants the second housing 20 to rotate.

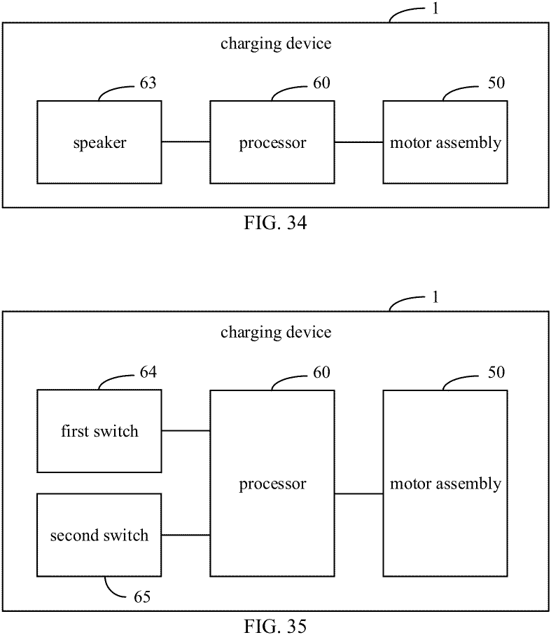

When the rotation angle of the second housing 20 is greater than or equal to the preset angle, it means that the second housing 20 has rotated to the angle value set by the user, and the second housing 20 is not expected to continue to rotate, so the processor 60 may be further configured to send a second control signal to the motor assembly 50 so that the motor assembly 50 stops working, and then the second housing 20 stops rotating, so that the charging device 1 finally reaches the user desired upright position. Specific reference is made to FIG. 34. FIG. 34 is a schematic view of the electronic structure of the charging device in another embodiment of the disclosure. In this embodiment, the charging device 1 further includes a speaker 63, and the speaker 63 is electrically connected to the processor. When the processor 60 sends the first control signal, the processor 60 may be further configured to send an audio signal to the speaker 63 to cause the speaker 63 to output a sound. When the processor 60 sends the second control signal to the motor assembly 50, the processor 60 may be further configured to stop sending the audio signal to the speaker 63, which causes the speaker 63 to stop outputting the sound.

In this embodiment, a speaker 63 may also be added in the first receiving space 100, so that the speaker 63 is electrically connected to the processor 60. When the processor 60 sends the first control signal to the motor assembly 50, the motor assembly 50 will start to work and move, and at this time, the processor 60 can send an audio signal to the speaker 63 to make the speaker 63 produce sound. Since the motor assembly 50 may generate some tiny noises during operation, the speaker 63 can be used to cover the noise, and different music can be played in different states in conjunction with the movement of the charging device 1 to improve user experience. In addition, when the processor 60 sends the second control signal to the motor assembly 50 so that the motor assembly 50 stops operating, the motor assembly 50 will not produce sound at this time, so the processor 60 can also stop sending the audio signal to the speaker 63, so that the speaker 63 also does not emit sound. Moreover, the user can also know when the charging device 1 starts working and stops working according to the sounding time of the speaker 63. In at least one alternative embodiment, a plurality of sound holes is opened on the first housing 10 to facilitate the sound from the speaker 63 to spread out of the charging device 1.

Specific reference is made to FIG. 35. FIG. 35 is a schematic view of the electronic structure of the charging device in another embodiment of the disclosure. In this embodiment, the charging device 1 further includes a first switch 64 and a second switch 65, both of which are electrically connected to the processor 60.

When the first switch 64 is pressed, the first switch 64 may be configured to send a vertical signal to the processor 60, and the processor 60 may be further configured to send the first control signal to motor assembly 50 according to the vertical signal, and then make the output shaft of the motor assembly 50 rotate in the first direction. When the second switch 65 is pressed, the second switch 65 may be configured to send a horizontal signal to the processor 60. The processor 60 is further configured to send a third control signal to the motor assembly 50 according to the horizontal signal, so as to make the output shaft of the motor assembly 50 rotate in a second direction. The first direction is opposite to the second direction.

In this embodiment, a first switch 64 and a second switch 65 can also be added in the first receiving space 100, the first switch 64 and the second switch 65 can be connected to the first housing 10, and the first switch 64 and the second switch 65 are is electrically connected to the processor 60. The first switch 64 and the second switch 65 are structural components for controlling when the charging device 1 starts to operate. Both the first switch 64 and the second switch 65 can be pressed. When the first switch 64 is pressed, the first switch 64 can send a vertical signal to the processor 60, and the processor 60 can send a first control signal to the motor assembly 50 according to the vertical signal, so that the motor assembly 50 starts to operate, and then the motor assembly 50 drives the second housing 20 to rotate along a first direction. It can also be understood that when the first switch 64 is pressed, the motor assembly 50 starts to work to convert the charging device 1 from the horizontal state to the vertical state. When the second switch 65 is pressed, the second switch 65 can send a horizontal signal to the processor 60, and the processor 60 may be further configured to send a fourth control signal to the motor assembly 50 according to the horizontal signal, Thus, the motor assembly 50 starts to operate again, and the motor assembly 50 can drive the second housing 20 to rotate in the second direction. It can also be understood that when the second switch 65 is pressed, the motor assembly 50 starts to operate to convert the charging device 1 from the vertical state to the horizontal state.

To sum up, the first switch 64 is a switch for controlling the transition of the charging device 1 from the horizontal state to the vertical state. The second switch 65 is a switch for controlling the transition of the charging device 1 from the vertical state to the horizontal state. The user can control the state of the charging device 1 by pressing the two switches, which improves the convenience of operation.

In at least one alternative embodiment, the processor 60 may be further configured to obtain the pressing time of the first switch 64 according to the vertical signal. The processor 60 may be further configured to judge whether the pressing time is less than a preset time. When the pressing time is less than the preset time, and when the sliding distance of the slider 52 is equal to the preset distance, the processor 60 sends the second control signal to the motor assembly 50, or when the pressing time is greater than or equal to the preset time, and when the touch force on the first switch 64 is removed, the processor 60 sends the second control signal to the motor assembly 50.

This embodiment provides two control modes according to the relationship between the pressing time and the preset time. In one control mode, when the pressing time is less than the preset time, and when the rotation angle of the second housing 20 is equal to the preset angle, the processor 60 sends the motor assembly 50 the second control signal used to stop the motor assembly 50 from working. It can also be understood that when the second housing 20 rotates to a maximum angle, the processor 60 can control the motor assembly 50 to stop working. In another control mode, when the pressing time is greater than or equal to the preset time, and when the touch force on the first switch 64 is removed, the processor 60 may send the second control signal to the motor assembly 50 to make the motor assembly 50 stop working. It can also be understood that when the pressing time of the first switch 64 is longer than the preset time, the user needs to actively remove the pressing force at this time, so that the motor assembly 50 can be controlled to stop working at any time, the second housing 20 stops rotating at any position.

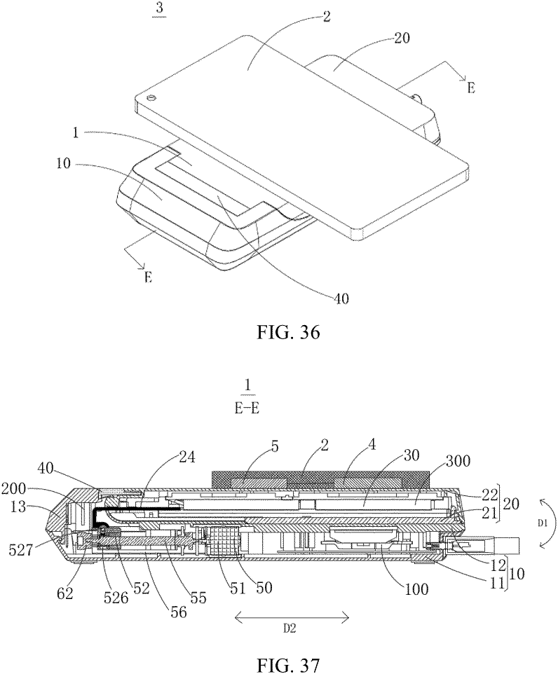

Specific reference is now made to FIGS. 36 and 37. FIG. 36 is a schematic structural view of an electronic device assembly in an embodiment of the disclosure. FIG. 37 is a schematic cross-sectional view of FIG. 36, taken along line E-E. This embodiment provides an electronic device assembly 3, the electronic device assembly 3 includes an electronic device 2, and the charging device 1 provided in the above embodiment of the disclosure. The electronic device 2 includes an induction coil 4 and a battery 5, so the charging coil 31 and the induction coil 4 cooperate with each other to charge the battery 5.

In addition to providing the specific structure of the charging device 1, this disclosure also provides an electronic device assembly 3 utilizing the charging device 1. The electronic device assembly 3 of this embodiment includes the electronic device 2 and the charging device 1 provided in the above embodiments of the disclosure. The electronic device 2 includes, but is not limited to a mobile phone, tablet computer, notebook computer, palmtop computer, personal computer (Personal Computer, PC), personal digital assistant (Personal Digital Assistant, PDA), portable media player (Portable Media Player, PMP), navigation devices, wearable devices, smart bracelets, pedometers and other mobile terminals, as well as fixed terminals such as digital TVs and desktop computers. The electronic device 2 includes an induction coil 4 and a battery 5, and when the charging device 1 starts charging, the charging coil 31 and the induction coil 4 cooperate with each other to charge the battery 5. The electronic device assembly 3 provided in this embodiment uses the charging device 1 provided in the above-mentioned embodiments of the disclosure to make the holder 40 follow the movement of the second housing 20, so that the holder 40 can be extended. The holder 40 not only limits the position of the electronic device 2 when the charging device 1 is in a vertical state, but also improves the surface flatness when the charging device 1 is in a horizontal state. This enhances the versatility and convenience of the charging device 1.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best use the invention and various described embodiments with various modifications as are suited to the particular use contemplated.

What is claimed is:

1. A charging device, comprising:
a first housing;
a second housing connected to the first housing and rotatable relative to the first housing, the second housing being configured to hold an electronic device;
a charging assembly received in the second housing, the charging assembly being configured to charge the electronic device; and
a holder connected to the first housing and rotatable along with rotation of the second housing, the holder being configured to switch between a protruding state, in which the holder extends out of the first housing, and a receiving state, in which the holder is received in the first housing.

2. The charging device according to claim 1, wherein an angle is formed between the second housing and the first housing when the second housing is rotating relative to the first housing;
wherein when the angle is a preset angle, the second housing is configured to abut the holder; and
wherein when the angle is larger than the preset angle, the second housing is configured to drive the holder to rotate.

3. The charging device according to claim 1, wherein the first housing comprises a first sub-housing and a second sub-housing,
wherein a protruding portion is arranged on a side of the second sub-housing, distal from the first sub-housing; and
wherein when the holder is in the receiving state, a surface of the holder is flush with a surface of the protruding portion.

4. The charging device according to claim 1, wherein a clearance space is defined between the second housing and the holder, the clearance space being configured to allow the second housing to rotate relative to the first housing.

5. The charging device according to claim 4, wherein the second housing comprises a third sub-housing and a fourth sub-housing, the third sub-housing being closer to the first sub-housing than the fourth sub-housing, and a first rotation portion being formed on a surface of the holder near the fourth sub-housing, and
wherein a second rotation portion and a third rotation portion are formed on a surface of the fourth sub-housing near the holder, the second rotation portion being further away from the first sub-housing than the first rotation portion, and the third rotation portion being closer to the first sub-housing than the first rotation portion.

6. The charging device according to claim 5, wherein the holder, the first rotation portion, the fourth sub-housing, and the second rotation portion surround an area to define the clearance space.

7. The charging device according to claim 5, wherein a surface of the holder distal from the first sub-housing, a surface of the second rotation portion distal from the first sub-housing, and a surface of the fourth sub-housing distal from the first sub-housing are flush with each other.

8. The charging device according to claim 4, wherein the second housing is further configured to be translational relative to the first housing to define the clearance space.

9. The charging device according to claim 1, wherein the charging device further comprises a motor assembly, the motor assembly being rotatably connected to the second housing, and the motor assembly being configured to drive the second housing to rotate relative to the first housing.

10. The charging device according to claim 1, wherein the charging device has a horizontal state and a vertical state; and
wherein when the holder is in the receiving state, the charging device is in the horizontal state, where the second housing is parallel to the first housing state; and
wherein when the holder is the protruding state, the charging device is in the vertical state, where the angle is formed between the second housing and the first housing.

11. The charging device according to claim 10, wherein the horizontal state comprises an initial state and a rearward state; and
wherein in the initial state, the second housing abuts the holder, and in the rearward state, the clearance space is defined between the second housing and the holder.

12. The charging device according to claim 1, wherein the charging assembly comprises a charging coil and a heat dissipation bracket, the charging coil being arranged on the heat dissipation bracket.

13. The charging device according to claim 1, wherein the charging device further comprises a transmission member; and
wherein when the second housing is rotating relative to the first housing, the second housing is configured to drive the transmission member to rotate, and rotation of the transmission member drives the holder to drive.

14. The charging device according to claim 13, wherein the second housing is separated from the first housing by a distance when the second housing is translating relative to the second housing;
wherein when the distance is less than a preset value, there is a gap between the transmission member and the holder;
wherein when the distance is the preset value, the second housing is configured to drive the transmission member to connect to the holder; and
wherein when the distance is greater than the preset value, the second housing is configured to drive the transmission member to rotate, and rotation of the transmission member drives the holder to drive.

15. A charging device, comprising:
a first housing;
a second housing connected to the first housing and rotatable relative to the first housing, the second housing being configured to hold an electronic device;
a charging assembly received in the second housing, the charging assembly being configured to charge the electronic device; and
a motor assembly being configured to receive a first control signal and a second control signal, the first control signal being configured to cause the motor assembly to drive the second housing to rotate relative to the first housing, and the second control signal being configured to cause the motor assembly to stop.

16. The charging device according to claim 15, wherein the charging device further comprises a processor, the processor being electrically connected to the motor assembly, and the processor being configured to transmit the first control signal and the second control signal.

17. The charging device according to claim 16, wherein the motor assembly comprises a motor and a slider, the motor being configured to drive the slider to slide, and the slide of the slider being configured to drive the second housing to rotate relative to the first housing.

18. The charging device according to claim 17, wherein the charging device further comprises a distance sensor;
wherein the distance sensor is electrically connected to the processor, and configured to detect the sliding distance of the slider;
wherein when the sliding distance of the slider is greater than or equal to a preset distance, the processor is configured to transmit the second control signal.

19. The charging device according to claim 16, wherein the charging device further comprises a first switch and a second switch, each of the first switch and the second switch being electrically connected to the processor;
wherein when the first switch is pressed, the first switch is configured to transmit a vertical signal to the processor, and the processor is configured to transmit the first control signal to the motor assembly according to the vertical signal, and the first control signal being configured to drive the motor assembly to rotate in the first direction;
wherein when the second switch is pressed, the second switch is configured to transmit a horizontal signal to the processor, the processor being configured to transmit a third control signal to the motor assembly according to the horizontal signal, and the third control signal is configured to drive the motor assembly to rotate in a second direction, opposite the first direction.

20. The charging device according to claim 15, further comprising a transceiver, the transceiver being electrically connected to the motor assembly, the transceiver being configured to receive the first control signal and the second control signal transmitted by the electronic device.
